(19) United States
(12) Patent Application Publication
(10) Pub. No.: US 2026/0058632 A1
(43) Pub. Date: Feb. 26, 2026

(54) BULK ACOUSTIC WAVE DEVICES WITH HIGH ACOUSTIC VELOCITY ELECTRODES

(71) Applicant: SKYWORKS GLOBAL PTE. LTD., Singapore (SG)

(72) Inventors: Michael David Hill, Emmitsburg, MD (US); Alexandre Augusto Shirakawa, Cardiff by the Sea, CA (US); Kwang Jae Shin, Yongin-si (KR); Stefan Bader, Fort Collins, CO (US); David Albert Feld, Los Altos, CA (US); Martha Kennedy Small, Fort Collins, CO (US); Benjamin Paul Abbott, Irvine, CA (US)

(21) Appl. No.: 19/304,752

(22) Filed: Aug. 20, 2025

Related U.S. Application Data
(60) Provisional application No. 63/686,340, filed on Aug. 23, 2024.

(51) Int. Cl. H03H 9/05; H03H 9/13; H03H 9/17; H03H 9/56

(52) U.S. Cl. CPC H03H 9/0504; H03H 9/131; H03H 9/172; H03H 9/568

(57) ABSTRACT

Aspects and embodiments disclosed herein include a bulk acoustic wave (BAW) device comprising a first electrode and a second electrode, at least one of the first electrode and the second electrode including at least one of a binary intermetallic compound, a metal nitride, a metal carbide, a metal carbonitride, a metal boride, a MXene, a MAX phase, or a MAB phase, and a piezoelectric material layer positioned between the first electrode and the second electrode.

### CROSS-REFERENCE TO RELATED APPLICATIONS

This application claims priority under 35 U.S.C. § 119(e) to U.S. Provisional Patent Application Ser. No. 63/686,340, titled “BULK ACOUSTIC WAVE DEVICES WITH HIGH ACOUSTIC VELOCITY ELECTRODES,” filed Aug. 23, 2024, the entire content of which is incorporated herein by reference for all purposes.

### BACKGROUND

### Field

Embodiments of this disclosure relate to acoustic wave devices, such as bulk acoustic wave devices.

### Description of the Related Technology

An acoustic wave filter can include a plurality of resonators arranged to filter a radio frequency signal. Example acoustic wave filters include surface acoustic wave (SAW) filters and bulk acoustic wave (BAW) filters. BAW filters include BAW resonators. Example BAW resonators include film bulk acoustic wave resonators and BAW solidly mounted resonators (SMRs). In BAW resonators, acoustic waves propagate in the bulk of a piezoelectric material layer.

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

Using conventional materials and manufacturing techniques, increasing the working frequency of a BAW resonator to above 6 GHz may involve decreasing the overall resonator thickness to very low levels. Realizing such thin resonators hitherto involves the application of specialized deposition techniques.

An acoustic wave device can include electrodes. Properties of the electrodes can impact performance of the acoustic wave device. For example, in a BAW device, a material of the electrodes in combination with the chosen thickness of the electrodes can impact the resonance frequency of the BAW device.

### SUMMARY

The innovations described in the claims each have several aspects, no single one of which is solely responsible for its desirable attributes. Without limiting the scope of the claims, some prominent features of this disclosure will now be briefly described.

According to some implementations, the present disclosure relates to a bulk acoustic wave (BAW) device. The BAW device includes a first electrode and a second electrode. At least one of the first electrode and the second electrode includes at least one of a binary intermetallic compound, a metal nitride, a metal carbide, a metal carbonitride, a metal boride, a MXene, a MAX phase, or a MAB phase. The BAW device further includes a piezoelectric material layer positioned between the first electrode and the second electrode.

As the term is used herein, a MXene can be represented by the general structural formula Mₙ₊₁XₙTx, where M is an early transition metal, X is C, B, CN, and/or N, and Tx represents surface terminations (if any).

As the terms are used herein, MAX and MAB phases are classes of nanolayered, hexagonal, machinable, early transition-metal carbides, borides, and nitrides. They can be generally expressed by the chemical formula Mₙ₊₁AXₙ, where M is an early transition metal, A is an A-group element (mostly groups 13 and 14), X is C, B, and/or N, and
n is 1, 2, or 3.

In some embodiments, the BAW device further includes a raised frame structure outside of a middle area of an active region of the BAW device. In several embodiments, the raised frame structure includes a raised frame layer positioned between one of the first and second electrodes and the piezoelectric material layer. In some embodiments, the raised frame layer has a lower acoustic impedance than the first or second electrode.

In line with a few embodiments, the raised frame layer is a silicon dioxide layer. According to a number of embodiments, the acoustic impedance of the raised frame layer is lower than an acoustic impedance of the piezoelectric material layer. In various embodiments, the raised frame layer is disposed in a raised frame domain of the BAW device along an edge of the active domain. In accordance with several embodiments, the BAW device further includes a recessed frame domain between the raised frame domain and the middle area.

According to some embodiments, the raised frame layer is positioned between the piezoelectric material layer and the first electrode.

In various embodiments, at least a part of the raised frame structure includes at least one of a binary intermetallic compound, a metal nitride, a metal carbide, a metal carbonitride, a metal boride, a MXene, a MAX phase, or a MAB phase.

In a number of embodiments, both the first electrode and the second electrode are formed of at least one of a binary intermetallic compound, a metal nitride, a metal carbide, a metal carbonitride, a metal boride, a MXene, a MAX phase, or a MAB phase. In various embodiments, the first electrode and the second electrode are formed of the same material. In some alternative embodiments, the first electrode and the second electrode are formed of different materials.

In some embodiments, at least one of the first electrode and the second electrode is formed of one of Al₃Ti, AlTi, AlTi₃, Al₃Sc, NiAl, Ni₃Al, CoAl, CoPt, AlCu, Al₂Cu, Cu₂Mg, or Cu_{0.019}Be.

In a number of embodiments, at least one of the first electrode and the second electrode is formed of one of TiN, ZrN, HfN, VN, NbN, CrN, or MoN_{0.6}. According to various embodiments, at least one of the first electrode and the second electrode is formed of one of TiC, ZrC, HfC, VC_{0.88}, NbC, TaC, Cr₃C₂, Mo₂C, or WC. In several embodiments, at least one of the first electrode and the second electrode is formed of one of a-AlB₂, a-TiB₂, a-VB₂, a-WB₂, ZrB₂, HfB₂, NbB₂, TaB₂, CrB₂₋ₓ, or Mo₂B₅₋ₓ.

In a few embodiments, at least one of the first electrode and the second electrode is formed of one of Ti₂AlN, Ti₂AlC, Ti₂SiC, Ti₂GeC, Ti₂SnC, Ti₃AlC₂, Ti₃GeC₂, Ti₃SiC₂, Mn₂AlB₂, Fe₂AlB₂, MoAlB, or WAlB.

According to some embodiments, at least one of the first electrode and the second electrode is manufactured as a sputtered film. According to some embodiments, at least one of the first electrode and the second electrode is manufactured by high temperature annealing, pulsed laser deposition (PLD), ion beam deposition (IBD), high power impulse magnetron sputtering (HiPIMS), or high density plasma chemical vapor deposition (HDP-CVD).

According to some implementations, the present disclosure relates to a film bulk acoustic wave resonator device. The film bulk acoustic wave resonator device includes a substrate and first and second conductive layers implemented over the substrate. At least one of the first and second conductive layers includes at least one of a binary intermetallic compound, a metal nitride, a metal carbide, a metal carbonitride, a metal boride, a MXene, a MAX phase, or a MAB phase. The film bulk acoustic wave resonator device further includes a piezoelectric material layer between the first and second conductive layers.

In some embodiments, the film bulk acoustic wave resonator device further includes a raised frame structure outside of a middle area of an active region of the film bulk acoustic wave resonator device. In several embodiments, the raised frame structure includes a raised frame layer positioned between one of the first and second conductive layers and the piezoelectric material layer. In some embodiments, the raised frame layer has a lower acoustic impedance than the first or second conductive layer.

In accordance with a few embodiments, the raised frame layer is a silicon dioxide layer. According to a number of embodiments, the acoustic impedance of the raised frame layer is lower than an acoustic impedance of the piezoelectric material layer. In various embodiments, the raised frame layer is disposed in a raised frame domain of the BAW device along an edge of the active domain. In accordance with several embodiments, the BAW device further includes a recessed frame domain between the raised frame domain and the middle area.

According to some embodiments, the raised frame layer is positioned between the piezoelectric material layer and the first conductive layer.

In various embodiments, at least a part of the raised frame structure includes at least one of a binary intermetallic compound, a metal nitride, a metal carbide, a metal carbonitride, a metal boride, a MXene, a MAX phase, or a MAB phase.

In a number of embodiments, both the first conductive layer and the second conductive layer are formed of at least one of a binary intermetallic compound, a metal nitride, a metal carbide, a metal carbonitride, a metal boride, a MXene, a MAX phase, or a MAB phase. In various embodiments, the first conductive layer and the second conductive layer are formed of the same material. In some alternative embodiments, the first conductive layer and the second conductive layer are formed of different materials.

In some embodiments, at least one of the first conductive layer and the second conductive layer is formed of one of Al₃Ti, AlTi, AlTi₃, Al₃Sc, NiAl, Ni₃Al, CoAl, CoPt, AlCu, Al₂Cu, Cu₂Mg, or Cu_{0.019}Be.

In a number of embodiments, at least one of the first conductive layer and the second conductive layer is formed of one of TiN, ZrN, HfN, VN, NbN, CrN, or MoN_{0.6}. According to various embodiments, at least one of the first conductive layer and the second conductive layer is formed of one of TiC, ZrC, HfC, VC_{0.88}, NbC, TaC, Cr₃C₂, Mo₂C, or WC. In several embodiments, at least one of the first conductive layer and the second conductive layer is formed of one of a-AlB₂, a-TiB₂, a-VB₂, a-WB₂, ZrB₂, HfB₂, NbB₂, TaB₂, CrB₂₋ₓ, or Mo₂B₅.

In a few embodiments, at least one of the first conductive layer and the second conductive layer is formed of one of Ti₂AlN, Ti₂AlC, Ti₂SiC, Ti₂GeC, Ti₂SnC, Ti₃AlC₂, Ti₃GeC₂, Ti₃SiC₂, Mn₂AlB₂, Fe₂AlB₂, MoAlB, or WAlB.

According to some embodiments, at least one of the first conductive layer and the second conductive layer is manufactured as a sputtered film. According to some embodiments, at least one of the first conductive layer and the second conductive layer is manufactured by high temperature annealing, pulsed laser deposition (PLD), ion beam deposition (IBD), high power impulse magnetron sputtering (HiPIMS), or high density plasma chemical vapor deposition (HDP-CVD).

According to some implementations, the present disclosure relates to a packaged module. The packaged module includes a packaging substrate and an acoustic wave filter on the packaging substrate configured to filter a radio frequency signal. The acoustic wave filter includes a bulk acoustic wave (BAW) device. The BAW device includes a first electrode and a second electrode. At least one of the first electrode and the second electrode includes at least one of a binary intermetallic compound, a metal nitride, a metal carbide, a metal carbonitride, a metal boride, a MXene, a MAX phase, or a MAB phase. The BAW device further includes a piezoelectric material layer positioned between the first electrode and the second electrode. The packaged module further includes a radio frequency component electrically coupled to the acoustic wave filter and positioned on the packaging substrate, the acoustic wave filter and the radio frequency component being enclosed within a common package.

In some embodiments, both the first electrode and the second electrode are formed of at least one of a binary intermetallic compound, a metal nitride, a metal carbide, a metal carbonitride, a metal boride, a MXene, a MAX phase, or a MAB phase.

In some embodiments, the first electrode and the second electrode are formed of the same material. In some embodiments, the first electrode and the second electrode are formed of different materials.

In some embodiments, at least one of the first electrode and the second electrode is formed of one of Al₃Ti, AlTi, AlTi₃, Al₃Sc, NiAl, Ni₃Al, CoAl, CoPt, AlCu, Al₂Cu, Cu₂Mg, or Cu_{0.019}Be. In some embodiments, at least one of the first electrode and the second electrode is formed of one of TiN, ZrN, HfN, VN, NbN, CrN, or MoN_{0.6}. In some embodiments, at least one of the first electrode and the second electrode is formed of one of TiC, ZrC, HfC, VC_{0.88}, NbC, TaC, Cr₃C₂, Mo₂C, or WC. In some embodiments, at least one of the first electrode and the second electrode is formed of one of a-AlB₂, a-TiB₂, a-VB₂, a-WB₂, ZrB₂, HfB₂, NbB₂, TaB₂, CrB₂-x, or Mo₂B₅₋ₓ. In some embodiments, at least one of the first electrode and the second electrode is formed of one of Ti₂AlN, Ti₂AlC, Ti₂SiC, Ti₂GeC, Ti₂SnC, Ti₃AlC₂, Ti₃GeC₂, Ti₃SiC₂, Mn₂AlB₂, Fe₂AlB₂, MoAlB, or WAlB.

In some embodiments, at least one of the first electrode and the second electrode is manufactured as a sputtered film.

According to some implementations, the present disclosure relates to a multiplexer. The multiplexer includes a first filter including a bulk acoustic wave (BAW) resonator. The BAW resonator includes a first electrode and a second electrode. At least one of the first electrode and the second electrode includes at least one of a binary intermetallic compound, a metal nitride, a metal carbide, a metal carbonitride, a metal boride, a MXene, a MAX phase, or a MAB phase. The BAW resonator further includes a piezoelectric material layer positioned between the first electrode and the second electrode. The multiplexer further includes a second filter coupled to the first filter at a common node and including at least one second BAW resonator, the first filter and the second filter together arranged to filter a radio frequency signal.

According to some implementations, the present disclosure relates to a radio frequency front end (RFFE). The RFFE includes an acoustic wave filter configured to filter a radio frequency signal. The acoustic wave filter includes a plurality of acoustic wave resonators including a bulk acoustic wave (BAW) resonator. The BAW resonator includes a first electrode and a second electrode. At least one of the first electrode and the second electrode include at least one of a binary intermetallic compound, a metal nitride, a metal carbide, a metal carbonitride, a metal boride, a MXene, a MAX phase, or a MAB phase. The BAW resonator further includes a piezoelectric material layer positioned between the first electrode and the second electrode. The RFFE further includes a radio frequency amplifier coupled to the acoustic wave filter.

According to some implementations, the present disclosure relates to a wireless communication device. The wireless communication device includes an acoustic wave filter configured to filter a radio frequency signal. The acoustic wave filter includes a bulk acoustic wave (BAW) device. The BAW device includes a first electrode and a second electrode. At least one of the first electrode and the second electrode include at least one of a binary intermetallic compound, a metal nitride, a metal carbide, a metal carbonitride, a metal boride, a MXene, a MAX phase, or a MAB phase. The BAW device further includes a piezoelectric material layer positioned between the first electrode and the second electrode. The wireless communication device further includes an antenna operatively coupled to the acoustic wave filter, a radio frequency amplifier operatively coupled to the acoustic wave filter and configured to amplify a radio frequency signal, and a transceiver in communication with the radio frequency amplifier.

For purposes of summarizing the disclosure, certain aspects, advantages and novel features have been described herein. It is to be understood that not necessarily all such advantages may be achieved in accordance with any particular embodiment. Thus, aspects and embodiments disclosed herein may be carried out in a manner that achieves or optimizes one advantage or group of advantages as taught herein without necessarily achieving other advantages as may be taught or suggested herein.

### BRIEF DESCRIPTION OF THE DRAWINGS

FIG. 1 is a schematic cross-sectional view of a bulk acoustic wave (BAW) device with a single-layer single-gradient raised frame structure according to an embodiment.

FIG. 2A is a cross sectional view of a multi-layer gradient raised frame BAW device according to another embodiment.

FIG. 2B is a cross sectional view of a multi-layer raised frame BAW device according to another embodiment.

FIG. 3A is a cross sectional diagram of a BAW device according to another embodiment.

FIG. 3B is an example plan view of the BAW device of FIG. 3A.

FIG. 4 is a schematic cross-sectional view of a BAW device with a dual gradient raised frame structure according to another embodiment.

FIG. 5 illustrates a BAW solidly mounted resonator with a dual gradient raised frame structure according to another embodiment.

FIG. 6 is a schematic diagram of a ladder filter that includes a BAW resonator according to another embodiment.

FIG. 7 is a schematic diagram of a further ladder filter that includes a BAW resonator according to another embodiment.

FIG. 8 is a schematic diagram of a lattice filter that includes a BAW resonator according to another embodiment.

FIG. 9 is a schematic diagram of a hybrid ladder lattice filter that includes a BAW resonator according to another embodiment.

FIG. 10A is a schematic diagram of an acoustic wave filter.

FIG. 10B is a schematic diagram of a duplexer that includes an acoustic wave filter according to another embodiment.

FIG. 10C is a schematic diagram of a multiplexer that includes an acoustic wave filter according to another embodiment.

FIG. 10D is a schematic diagram of another multiplexer that includes an acoustic wave filter according to another embodiment.

FIG. 10E is a schematic diagram of yet another multiplexer that includes an acoustic wave filter according to another embodiment.

FIG. 11 is a schematic block diagram of an illustrative packaged module according to another embodiment.

FIG. 12 is a schematic block diagram of another illustrative packaged module according to another embodiment.

FIG. 13 is a schematic block diagram of another illustrative packaged module according to another embodiment.

FIG. 14 is a schematic block diagram of another illustrative packaged module according to another embodiment.

FIG. 15 is a schematic block diagram of another illustrative packaged module according to another embodiment.

FIG. 16 is a schematic block diagram of a mobile device that includes acoustic wave filters with BAW resonators according to another embodiment.

FIG. 17 is a schematic diagram of a communication network.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

As demand increases for filtering radio frequency signals with higher frequencies, acoustic wave resonators with higher resonant frequencies are desired. Bulk acoustic wave (BAW) resonators are moving to increasingly higher resonant frequencies approaching 10 gigahertz (GHz). Bulk acoustic wave (BAW) resonators can use a fundamental mode as a main mode. In such BAW resonators, higher resonant frequencies can be achieved by reducing thicknesses of the piezoelectric material and/or electrode layers. BAW resonators with a thinner layer stack have generally provided higher resonant frequencies. Thinner electrodes can also contribute to a higher resonant frequency for a BAW resonator.

Thinner BAW stacks present technical challenges. With a thinner stack, BAW resonators are typically more fragile. Overall thickness of thinner BAW piezoelectric material and/or electrode layer stacks can be problematic for mechanical stability of a BAW resonator. BAW resonators with thin piezoelectric material and/or electrode layer stacks can be problematic for post-release processing, such as trimming, applying photoresists, and/or other processing that applies stress on a BAW resonator structure. BAW resonators with relatively thin piezoelectric material and/or electrode layer stacks can have relatively high resistivity. BAW resonators with relatively thin piezoelectric material and/or electrode layer stacks can exhibit technical challenges related to power handling. Moreover, thinner electrode layers can have higher electrode resistance that can reduce performance, for example, the quality factor Q.

The resonant frequency of a BAW resonator is proportional to the acoustic velocity of the resonator piezoelectric material and electrode layer stack divided by twice the resonator thickness. Therefore, to increase the frequency of a BAW resonator to frequencies above 6 GHz, one may utilize very thin resonator thicknesses using conventional materials. Due to the aforementioned difficulties and technical challenges, ever increasing frequencies set practical boundaries for the manufacturing of BAW resonators and, hence, BAW filters using conventional manufacturing techniques.

Since the acoustic velocity of a material is equivalent to the square root of the elastic modulus divided by the density, electrodes of BAW resonators being manufactured from low resistivity materials such as intermetallic compounds, borides, carbides and nitrides with high elastic moduli (c11 or c33) and low densities may provide for breakthroughs through the practical boundaries referenced above. There exist a number of binary and ternary carbides which have been shown to have low resistivity values as sputtered films.

An advantage of manufacturing electrodes of BAW resonators from such materials is that conventional processing techniques may be applied to create the BAW resonators with thicknesses similar to the current state of the art in BAW filter design. Moreover, creating complex internal structures within other elements of the BAW resonator to achieve resonance in the 6 GHz to 10 GHz range may be avoided.

A first example class of materials that may be used to manufacture electrodes of BAW devices or BAW resonators are low resistivity binary intermetallic compounds. Such compounds combine metallic, ionic, and covalent bonding. Binary intermetallic compounds generally have distinct band structures leading to very low resistivity values. Moreover, their carrier concentration and mobility is related to the density of states at the Fermi level so that their mean free path product of resistivity and Fermi length is expected to decrease. The combination of covalent and metallic bonding characteristics found in many intermetallic compounds results in complex electron hybridization, leading to high elastic moduli, high cohesive energy levels and, hence, high melting temperatures. Examples of candidate intermetallic compounds to be used to manufacture electrodes of BAW devices or BAW resonators, along with the respective relevant electromechanical properties are given in Table 1.

TABLE 1

| | Young's | | Acoustic | Acoustic | Melting | Electrical | |
|---|---|---|---|---|---|---|---|
| Intermetallic | Modulus | Density | Velocity | Impedance | Point | Resistivity | Poisson |
| compound | (GPa) | (g/cm³) | (m/s) | (MRayl/m²) | (° C.) | (μΩ*cm) | Ratio |
| Al (comparison) | 70 | 2.70 | 5092 | 13.75 | 660 | 2.7 | |
| Al₃Ti | 216 | 3.40 | 7971 | 27.10 | 1360 | 100 | |
| AlTi | 173 | 3.90 | 6660 | 25.97 | 1450 | 60 | |
| AlTi₃ | 147 | 4.20 | 5916 | 24.85 | 1600 | | |
| Al₃Sc | 170 | 3.11 | 7393 | 22.99 | 1283 | 12-30 | 173 |
| NiAl | 186-222 | 5.90 | 5614 | 33.12 | 1638 | 13.9 | 0.26 |
| Ni₃Al | 235 (calc) | | | | | | 0.28 |
| CoAl | | | | | | 30 | |
| CoPt | | | | | | | |
| AlCu | 172 | 5.00 | 5865 | 29.33 | 590 | 10 | |
| Al₂Cu | 125 | 4.30 | 5392 | 23.18 | 620 | 10 | |
| Cu₂Mg | | 5.71 | | | | 25-30 | |
| Cu_{0.019}Be | 131 | 8.25 | 3985 | 32.8 | 866 | 5-10 | |

A second example class of materials that may be used to manufacture electrodes of BAW devices or BAW resonators are low resistivity binary metal nitrides, carbides, carbonitrides, and borides. Similar to the binary intermetallic compounds, these materials exhibit strong covalent and metallic bonding, leading to low resistivity values due to their distinct band structures. Additionally, MXenes can be used to manufacture electrodes of BAW devices or BAW resonators. MXenes can be represented by the general structural formula Mₙ₊₁XₙTx, where M is an early transition metal, X is C, B, CN, and/or N, and Tx represents surface terminations (if any). MXenes as a particular class of refractory compounds generally exhibit high mechanical strengths and high values of Young's modulus while at the same time having good electrical conductivity. Examples of candidate binary metal nitrides, carbides, carbonitrides, and borides to be used to manufacture electrodes of BAW devices or BAW resonators, along with the respective relevant electromechanical properties are given in Tables 2a (candidate metal nitrides), 2b (candidate metal carbides), and 2c (candidate metal borides).

TABLE 2a

| | Young's | | Acoustic | Acoustic | Melting | Bulk |
|---|---|---|---|---|---|---|
| Metal | Modulus | Density | Velocity | Impedance | Point | Resistivity |
| Nitride | (GPa) | (g/cm³) | (m/s) | (MRayl/m²) | (° C.) | (μΩ*cm) |
| TiN | 420 | 5.39 | 8827 | 47.58 | 3050 | 27 |
| ZrN | 460 | 7.32 | 7966 | 56.48 | 3000 | 24 |
| HfN | 380 | 13.83 | 5242 | 72.49 | 3330 | 27 |
| VN | 380 | 6.04 | 7932 | 47.91 | 2350 | 65 |
| NbN | 360 | 8.16 | 6642 | 54.20 | | 60 |
| CrN | 450 | 6.14 | 8560 | 52.56 | | 640 |
| MoN_{0.6} | | 9.84 | | | | |

TABLE 2b

| | Young's | | Acoustic | Acoustic | Melting | Bulk |
|---|---|---|---|---|---|---|
| Metal | Modulus | Density | Velocity | Impedance | Point | Resistivity |
| Carbide | (GPa) | (g/cm³) | (m/s) | (MRayl/m²) | (° C.) | (μΩ*cm) |
| TiC | 450 | 4.93 | 9553 | 47.10 | 3067 | 100 |
| ZrC | 350 | 6.46 | 7361 | 47.55 | 3420 | 75 |
| HfC | 420 | 12.3 | 5843 | 71.87 | 3930 | 67 |
| VC_{0.88} | 430 | 5.36 | 8957 | 48.01 | 2650 | 69 |
| NbC | 340 | 7.78 | 6610 | 51.43 | 3610 | 20 |
| TaC | 290 | 14.48 | 4475 | 64.80 | 3985 | 15 |
| Cr₃C₂ | 380 | 6.68 | 7542 | 50.38 | 1810 | 75 |
| Mo₂C | 530 | 9.18 | 7598 | 69.75 | 2520 | 57 |
| WC | 707 | 15.72 | 6706 | 105.42 | 2776 | 17 |

TABLE 2c

| | Young's | | Acoustic | Acoustic | Melting | Bulk |
|---|---|---|---|---|---|---|
| Metal | Modulus | Density | Velocity | Impedance | Point | Resistivity |
| Boride | (GPa) | (g/cm³) | (m/s) | (MRayl/m²) | (° C.) | (μΩ*cm) |
| a-AlB₂ | 430 | 3.19 | 11610 | 37.04 | 920 | 31-77 |
| a-TiB₂ | 550 | 4.50 | 11055 | 49.75 | 2980 | 9-15 |
| a-VB₂ | 450 | 5.10 | 9393 | 47.91 | 2100 | 13-41 |
| a-WB₂ | 500 | 10.8 | 6813 | 73.38 | 2600 | 170 |
| ZrB₂ | 450 | 6.08 | 8603 | 52.31 | 3040 | 7-10 |
| HfB₂ | 473 | 10.5 | 6711 | 70.47 | 3250 | 10-12 |
| NbB₂ | 508-522 | 6.97 | 8537 | 59.50 | 3050 | 12 |
| TaB₂ | 519 | 11.2 | 6807 | 76.24 | 3200 | 14 |
| CrB₂₋ₓ | 400 | 5.22 | 8753 | 45.69 | 2170 | 18-80 |
| Mo₂B₅₋ₓ | 525 | 9.26 | 7530 | 69.72 | 2100 | 18-45 |

A third example class of materials that may be used to manufacture electrodes of BAW devices or BAW resonators are low resistivity ternary metal nitrides and carbides, commonly referred to as M-A-X phases (sometimes referred to as MAX phases). Analogously, low resistivity ternary metal borides are commonly referred to as M-A-B phases (sometimes referred to as MAB phases). MAX/MAB phases are a class of nanolayered, hexagonal, machinable, early transition-metal carbides, borides, and nitrides. They can be generally expressed by the chemical formula Mₙ₊₁AXₙ, where M is an early transition metal, A is an A-group element (mostly groups 13 and 14), X is C, B, and/or N, and n is 1, 2, or 3.

MAX/MAB phases are characterized by a unique combination of both metallic and ceramic properties due to their composition of nanolayers of edge-sharing, distorted XM6 octahedra interleaved by single planar layers of the A-group element. MAX/MAB phases generally exhibit high hardness and strength, good thermal and electrical conductivity, high resistance to corrosion and wear, as well as good machinability. Examples of candidate MAX/MAB phases to be used to manufacture electrodes of BAW devices or BAW resonators, along with the respective relevant electromechanical properties are given in Table 3.

TABLE 3

| | | | | | | Thin Film | |
|---|---|---|---|---|---|---|---|
| | Young's | | Acoustic | Acoustic | | Electrical | |
| MAX/MAB | Modulus | Density | Velocity | Impedance | Melting | Resistivity | Poisson |
| phase | (GPa) | (g/cm³) | (m/s) | (MRayl/m²) | Point | (μΩ*cm) | Ratio |
| Ti₂AlN | 300 | 4.26 | 8392 | 35.75 | High | 39 (sputtered) | 0.2 |
| Ti₂AlC | 294 | 3.99 | 8584 | 34.25 | High | 44 (sputtered) | 0.18 |
| Ti₂SiC | 275 | 4.34 | 7960 | 34.54 | High | 21-51 | 0.22 |
| Ti₂GeC | 300 | 5.56 | 7345 | 40.84 | High | 15-50 | 0.22 |
| Ti₂SnC | 207 | 6.31 | 5727 | 36.14 | High | 20-46 | 0.24 |
| Ti₃AlC₂ | 320 | 4.21 | 8718 | 36.70 | High | 30-51 | 0.19 |
| Ti₃GeC₂ | 197 | 5.55 | 5958 | 33.07 | High | 30-50 | 0.19 |
| Ti₃SiC₂ | 340-370 | 4.53 | 8663 | 39.24 | High | 25 | 0.19 |
| Mn₂AlB₂ | 407 | 5.65 | 8487 | 47.95 | High | 500-540 | |
| Fe₂AlB₂ | 348 | 5.75 | 7779 | 44.73 | High | 200-270 | |
| MoAlB | 350 | 6.45 | 7366 | 47.51 | High | 6-67 | |
| WAlB | 362 | 10.7 | 5827 | 62.12 | High | 244 | |

Since the acoustic velocity of a material is equivalent to the square root of the elastic modulus divided by the density, low resistivity materials such as intermetallic compounds, borides, carbides, and nitrides with high elastic moduli (c11 or c33) and low densities are viable candidates for the material used to manufacture electrodes of BAW devices and BAW resonators. As shown above in Tables 1, 2a, 2b, 2c, and 3, a number of intermetallic compounds, metal nitrides, metal carbides, metal carbonitrides, metal borides, MXenes, MAX phases, and MAB phases meet these criteria and have been shown to have low resistivity values as sputtered films.

Such sputtered films may, in some implementations, be created by DC magnetron sputtering. Many intermetallic compounds, metal nitrides, metal carbides, metal carbonitrides, and metal borides have highly ordered lattices and deviation from that order increases resistivity significantly. Thus, in some alternative implementations, films of such electrode materials for BAW devices and BAW resonators may be manufactured by high temperature annealing, pulsed laser deposition (PLD), ion beam deposition (IBD), high power impulse magnetron sputtering (HiPIMS), or high density plasma chemical vapor deposition (HDP-CVD). Such deposition methods create highly energetic and highly ionized plasmas that give incoming atoms on the growing film enough energy to find their correct place. Alternative implementations may utilize atomic layer deposition (ALD) which provides for layered deposition as well.

Although embodiments disclosed herein may be discussed with reference to bulk acoustic wave (BAW) devices, such as film bulk acoustic wave resonators or solidly mounted resonators (SMR), any suitable principles and advantages discussed herein can be applied to other acoustic wave devices, such as non-temperature compensated surface acoustic wave (SAW) devices, temperature compensated SAW (TC-SAW) devices and multilayer piezoelectric substrate (MPS) SAW devices, boundary wave devices, and Lamb wave devices as well.

Example BAW devices with electrodes manufactured from low resistivity materials with high elastic moduli and low densities will now be discussed. BAW devices may have electrodes manufactured from binary intermetallic compounds, MXenes, MAX phases, or MAB phases as selected from any of the candidates listed in Tables 1, 2a, 2b, 2c, and 3 above. Any suitable principles and advantages of these BAW devices can be implemented in BAW resonators. Such BAW resonators may be used for acoustic wave filters. Such acoustic wave filters can filter radio-frequency signals. The electrodes disclosed herein can be implemented in BAW devices. In BAW devices, electrodes having a higher acoustic velocity can contribute to a higher resonant frequency for a given electrode thickness. A BAW device with electrodes in accordance with any suitable principles and advantages disclosed herein can have a resonant frequency of at least 6 GHz. A BAW device with electrodes in accordance with any suitable principles and advantages disclosed herein can have a resonant frequency in a range from 6 GHz to 15 GHz. In some of these instances, a BAW device as disclosed herein can have a resonant frequency in a range from 6 GHz to 10 GHz. A BAW device with thicker electrodes having a higher acoustic velocity can have a same resonant frequency as another BAW device with thinner electrodes and a lower acoustic velocity. BAW resonators, such as film bulk acoustic wave resonators and BAW SMRs, can include electrodes in accordance with any suitable principles and advantages disclosed herein.

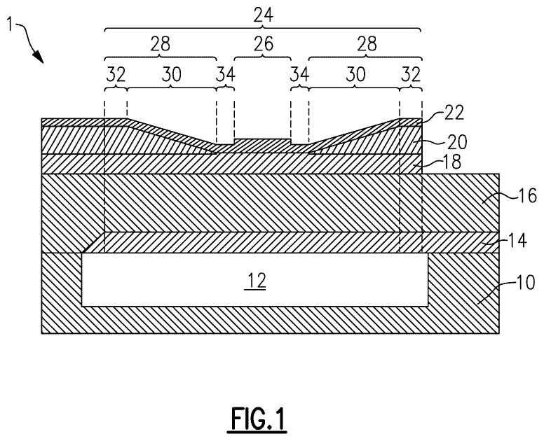

FIG. 1 is a schematic cross-sectional view of a BAW device 1. The BAW device 1 includes a support substrate 10, a cavity 12, a lower electrode 14 positioned over the support substrate 10, a piezoelectric material layer 16 positioned over the lower electrode 14, an upper electrode 18 positioned over the piezoelectric material layer 16, a raised frame structure 20 positioned over the upper electrode 18, and a passivation layer 22 positioned over the raised frame structure 20. The support substrate 10 can be a silicon substrate. Other suitable substrates can alternatively be implemented in place of the silicon substrate. One or more layers, such as a passivation layer, can be positioned between the lower electrode 14 and the support substrate 10. The cavity 12 can be an air cavity.

The piezoelectric material layer 16 can be an aluminum nitride (AlN) layer or any other suitable piezoelectric material layer. An active region 24 or active domain of the BAW device 1 is defined by the portion of the piezoelectric material layer 16 that overlaps with both the lower electrode 14 and the upper electrode 18 over an acoustic reflector, such as the cavity 12. The lower electrode 14 can have a relatively high acoustic impedance. Similarly, the upper electrode 18 can have a relatively high acoustic impedance. The upper electrode 18 can be formed of the same material as the lower electrode 14 in certain instances. In other instances, the lower electrode 14 and the upper electrode 18 can include different materials.

The upper electrode 18 may be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above. The lower electrode 14 may be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above.

The illustrated BAW device 1 includes the active region 24 that has a main acoustically active region 26 and a frame region 28 on opposing sides of the main acoustically active region 26. The main acoustically active region 26 may be referred to as a center region of the active region 24. The main acoustically active region 26 can set the fundamental resonant frequency of the BAW device 1. There can be a significant (e.g., exponential) fall off of acoustic energy in the piezoelectric material layer 16 for a main mode in the frame region 28 relative to the main acoustically active region 26. In the frame region 28, there is a gradient region 30 and a non-gradient region 32. The raised frame structure 20 can be a metal raised frame in some embodiments. The raised frame structure 20 can be substantially parallel to the piezoelectric material layer 16 in the non-gradient region 32. The raised frame structure 20 has a non-gradient portion in the non-gradient region 32 and a gradient portion in the gradient region 30. The active region 24 can include a recessed frame region 34.

The raised frame structure 20 can include a relatively high density material. For instance, the raised frame structure 20 can include molybdenum (Mo), tungsten (W), ruthenium (Ru), platinum (Pt), iridium (Ir), the like, or any suitable alloy thereof. The raised frame structure 20 can be a metal layer. Alternatively, the raised frame structure 20 can be a suitable non-metal material with a relatively high density. The density of the raised frame structure 20 can be similar to or heavier than the density of an electrode 14, 18 of the BAW device 1. In some instances, the raised frame structure 20 can be of the same material as an electrode 14, 18 of the BAW device 1. For example, the raised frame structure 20 can be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above. The raised frame structure 20 can have a relatively high acoustic impedance. The frame region 28 can surround the main acoustically active region 26 in plan view.

The BAW device 1 illustrated in FIG. 1 can be particularly beneficial for achieving relatively high Q below a resonant frequency (fₛ). The recessed frame region 34 can contribute to achieving the relatively high Q below the fₛ. The raised frame structure 20 can contribute to achieving the relatively high Q below the fₛ. The combination of the recessed frame region 34 and the raised frame structure 20 of the BAW device 1 can contribute to achieving the relatively high Q below the fₛ.

Example BAW devices with multi-layer (e.g., dual-layer) raised frame structures will now be discussed. Any suitable principles and advantages of these BAW devices can be implemented together with each other.

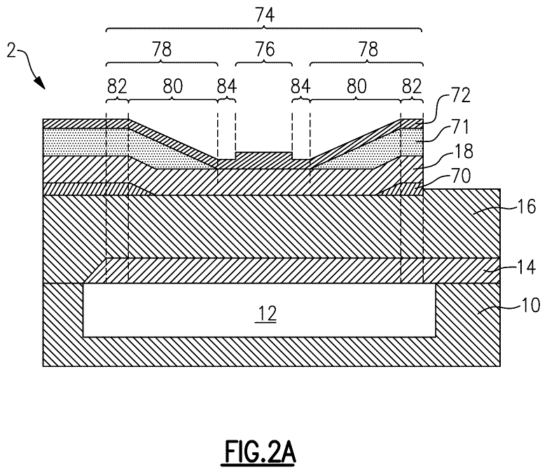

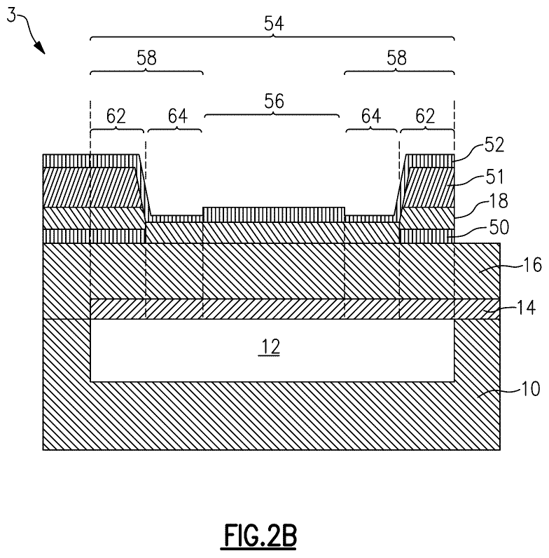

FIG. 2A is a cross-sectional side view of a multi-layer gradient raised frame bulk acoustic wave (BAW) device 2 according to an embodiment. As illustrated, the multi-layer gradient raised frame BAW device 2 includes a support substrate 10, a cavity 12, a lower electrode 14 positioned over the support substrate 10, a piezoelectric material layer 16 positioned over the lower electrode 14, an upper electrode 18 positioned over the piezoelectric material layer 16, a first raised frame structure 70 positioned at least partially between the piezoelectric material layer 16 and the upper electrode 18, a second raised frame structure 71 positioned over the upper electrode 18, and a passivation layer 72 positioned over the second raised frame structure 71. The BAW device 2 is generally similar to the BAW device 1 of FIG. 1, except the BAW device 2 additionally includes the first raised frame structure 70 between the piezoelectric material layer 16 and the upper electrode 18. The first raised frame structure 70 can also impact the geometry of overlying layers of the BAW device 2.

The illustrated BAW device 2 includes an active region 74 that has a main acoustically active region 76 and a frame region 78 on opposing sides of the main acoustically active region 76. The frame region 78 can surround the main acoustically active region 76 in a plan view. The main acoustically active region 76 may be referred to as a center region of the active region 74. The main acoustically active region 76 can set the fundamental resonant frequency of the BAW device 2. There can be a significant (e.g., exponential) fall off of acoustic energy in the piezoelectric material layer 16 for a main mode in the frame region 78 relative to the main acoustically active region 76. In the frame region 78, there is a gradient region 80 and a non-gradient region 82. The first raised frame structure 70 can reduce an effective electromechanical coupling coefficient (kₜ²) of the raised frame domain of the BAW device 2 relative to a similar device without the first raised frame structure 70, such as the BAW device 1 illustrated in FIG. 1. The second raised frame structure 71 can be a metal raised frame in some embodiments. In some instances, the second raised frame structure 71 can be formed of the same material as an electrode 14, 18 of the BAW device 2. For example, the second raised frame structure 71 can be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above. The second raised frame structure 71 can have a relatively high acoustic impedance. The first raised frame structure 70 and the second raised frame structure 71 can be substantially parallel to the piezoelectric material layer 16 in the non-gradient region 82. The second raised frame structure 71 has a non-gradient portion in the non-gradient region 82 and a gradient portion in the gradient region 80. The active region 74 can include a recessed frame region 84.

FIG. 2B is a cross-sectional side view of a multi-layer raised frame bulk acoustic wave (BAW) device 3 according to an embodiment. As illustrated, the multi-layer raised frame BAW device 3 includes a support substrate 10, a cavity 12, a lower electrode 14 positioned over the support substrate 10, a piezoelectric material layer 16 positioned over the lower electrode 14, an upper electrode 18 positioned over the piezoelectric material layer 16, a first raised frame structure 50 positioned at least partially between the piezoelectric material layer 16 and the upper electrode 18, a second raised frame structure 51 positioned over the upper electrode 18, and a passivation layer 52 positioned over the second raised frame structure 51. The BAW device 3 is generally similar to the BAW device 2 illustrated in FIG. 2A, except in BAW device 2, the first raised frame structure 70 and the second raised frame structure 71 have a gradient.

The upper electrode 18 may be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above. The lower electrode 14 may be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above.

The piezoelectric material layer 16 is disposed between the lower electrode 14 and the upper electrode 18. The piezoelectric material layer 16 can be an aluminum nitride (AlN) layer or any other suitable piezoelectric material layer. An active region 54 or active domain of the BAW device 3 is defined by the portion of the piezoelectric material layer 16 that overlaps with both the lower electrode 14 and the upper electrode 18 over an acoustic reflector, such as the cavity 12.

The dual raised frame structure of the BAW device 3 includes the first raised frame structure 50 and the second raised frame structure 51. The first raised frame structure 50 and the second raised frame structure 51 overlap with each other in the active region 54 of the BAW device 3. The active region 54 includes a main acoustically active region 56, and a frame region 58. The frame region 58 includes a raised frame region 62 and a recessed frame region 64. The raised frame region 62 of the BAW device 3 is defined by the portion of the dual raised frame structure in the active region 54 of the BAW device 3. At least a portion of the dual raised frame structure is included in the active region 54 of the BAW device 3. The dual raised frame structure can improve Q of the BAW device 3 significantly due to highly efficient reflection of lateral energy. The dual raised frame structure can achieve a relatively high Q above a resonant frequency (fₛ) and an anti-resonant frequency (fₚ) of the BAW device 3.

The first raised frame structure 50 is positioned between the lower electrode 14 and the upper electrode 18. As illustrated in FIG. 2B, the first raised frame structure 50 is positioned between the piezoelectric material layer 16 and the upper electrode 18. The first raised frame structure 50 includes and/or consists essentially of a low acoustic impedance material. The low acoustic impedance material can have a lower acoustic impedance than the lower electrode 14. The low acoustic impedance material can have a lower acoustic impedance than the upper electrode 18. The low acoustic impedance material can have a lower acoustic impedance than the piezoelectric material layer 16. As an example, the first raised frame structure 50 can be a silicon dioxide (SiO₂) layer. Because silicon dioxide is already used in a variety of bulk acoustic wave devices, a silicon dioxide first raised frame structure 50 can be relatively easy to manufacture. The first raised frame structure 50 can be a silicon nitride (SiN) layer, a silicon carbide (SiC) layer, or any other suitable low acoustic impedance layer. In some implementations, the first raised frame structure 50 can be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above. The first raised frame structure 50 can have a relatively low density. The first raised frame structure 50 can extend beyond the active region of the BAW device 3 as shown in FIG. 2B. This can be for manufacturability reasons in certain instances.

The first raised frame structure 50 can reduce an effective electromechanical coupling coefficient (kₜ²) of the raised frame domain of the BAW device 3 relative to a similar device without the first raised frame structure 50. This can reduce excitation strength of a raised frame spurious mode. Moreover, the first raised frame structure 50 can contribute to moving the frequency of the raised frame mode relatively far away from the resonant frequency of the BAW device 3, which can result in no significant Gamma loss.

As illustrated, the second raised frame structure 51 overlaps with the first raised frame structure 50 in the active region 54 of the BAW device 3. The second raised frame structure 51 can be formed of the same material as the upper electrode 18. This can be convenient from a manufacturing perspective. The second raised frame structure 51 can be a relatively high density material. For instance, the second raised frame structure 51 can include molybdenum (Mo), tungsten (W), ruthenium (Ru), the like, or any suitable alloy thereof. The second raised frame structure 51 can be a metal layer. Alternatively, the second raised frame structure 51 can be a suitable non-metal material with a relatively high density. In some implementations, the second raised frame structure 51 can, for example, be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above. The density of the second raised frame structure 51 can be similar to or greater than the density of the upper electrode 18. The second raised frame structure 51 can have a relatively high acoustic impedance.

The second raised frame structure 51 increases the height of the BAW device 3 in the raised frame domain. Accordingly, the BAW device 3 has a greater height in the raised frame domain than in other portions of the active domain, such as the middle area of the active domain. Forming the second raised frame structure 51 over the upper electrode 18 can be relatively easy from a manufacturing perspective. However, in some other embodiments, a second raised frame layer can be included in a different position in the stack of layers in the raised frame domain.

In the BAW device 3, a passivation layer 52 is included over the upper electrode 18 and the second raised frame structure 51. The passivation layer 52 can be a silicon dioxide layer. The passivation layer 52 can be formed with different thicknesses in different regions of the BAW device 3. For example, as shown in FIG. 2B, the passivation layer 52 is thinner in a recessed frame domain or the recessed frame region 64. Any suitable passivation material can be included in the passivation layer 52.

The dual raised frame BAW device 3 is a film bulk acoustic wave resonator. The cavity 12 (e.g., an air cavity) is included below the lower electrode 14. The cavity 12 is defined by the geometry of the lower electrode 14 and the support substrate 10. One or more layers, such as a passivation layer, can be positioned between the lower electrode 14 and the support substrate 10.

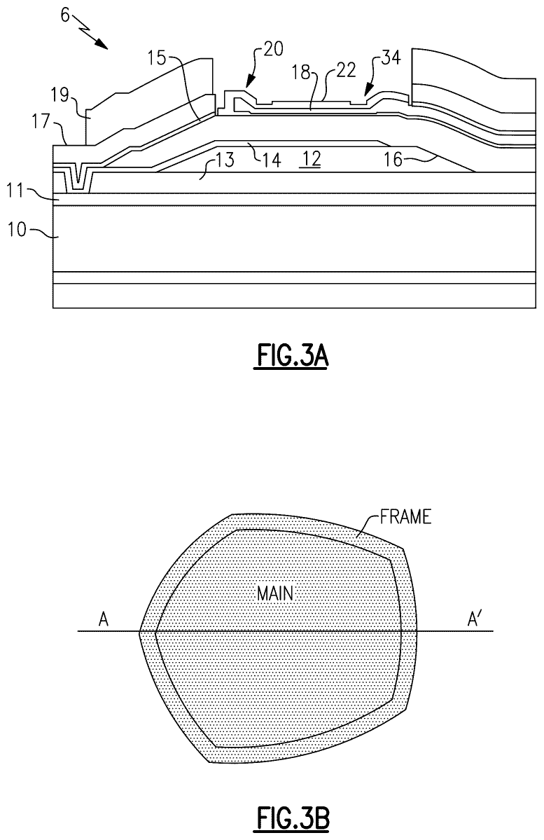

FIG. 3A is a cross-sectional diagram of a BAW device 6 according to another embodiment. As illustrated in FIG. 3A, the BAW device 6 includes a support substrate 10, a trap rich layer 11, a first passivation layer 13, an air cavity 12, a first electrode 14, a piezoelectric material layer 16, a second electrode 18, and a second passivation layer 22. The BAW device 6 also includes a recessed frame structure 34 and a raised frame structure 20.

The support substrate 10 can be a semiconductor substrate. The support substrate 10 can be a silicon substrate. The support substrate 10 can be any other suitable support substrate. The trap rich layer 11 can be a polysilicon layer, an amorphous silicon layer, or the like. The trap rich layer 11 is positioned between the support substrate 10 and the first passivation layer 13. The first passivation layer 13 can be referred to as a lower passivation layer. The first passivation layer 13 can be referred to as a bottom oxide layer when the lower passivation layer includes an oxide. The first passivation layer 13 can be a silicon dioxide layer or any other suitable passivation layer, such as aluminum oxide, silicon carbide, aluminum nitride, silicon nitride, silicon oxynitride, or the like.

The air cavity 12 is an example of an acoustic reflector. As illustrated, the air cavity 12 is located above the support substrate 10. The air cavity 12 is positioned between the support substrate 10 and the first electrode 14. In some embodiments, an air cavity can be etched into a support substrate, similar to the air cavity 12 in FIGS. 1, 2A, and 2B. In certain embodiments, a solid acoustic mirror with alternating high acoustic impedance and low acoustic impedance layers can be included in place of an air cavity. A BAW device with an air cavity can be referred to as an film bulk acoustic wave resonator. A BAW device with a solid acoustic mirror can be referred to as a BAW SMR.

The first electrode 14 can be referred to as a lower electrode. The first electrode 14 can have a relatively high acoustic impedance. Similarly, the second electrode 18 can have a relatively high acoustic impedance. The second electrode 18 can be formed of the same material as the first electrode 14 in certain instances. The second electrode 18 can be referred to as an upper electrode. The thickness of the first electrode 14 can be approximately the same as the thickness of the second electrode 18 in a main acoustically active region of the BAW device 6. The first electrode 14 and the second electrode 18 can be the only electrodes of the BAW device 6. The second electrode 18 may be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above. The first electrode 14 may be manufactured from binary intermetallic compounds, metal nitrides, metal carbides, metal carbonitrides, metal borides, MXenes, MAX phases, or MAB phases as selected from any of the candidates listed in Tables 1, 2a, 2b, 2c, and 3 above.

The second passivation layer 22 can be referred to as an upper passivation layer. The second passivation layer 22 can be a silicon dioxide layer or any other suitable passivation layer, such as aluminum oxide, silicon carbide, aluminum nitride, silicon nitride, silicon oxynitride, or the like. The second passivation layer 22 can be the same material as the first passivation layer 13 in certain instances. The second passivation layer 22 can have different thicknesses in different regions of the BAW device 6. Part of the second passivation layer 22 can form at least part of the recessed frame structure 34 and/or the raised frame structure 20.

An active region or active domain of the BAW device 6 can be defined by a portion of the piezoelectric material layer 16 that overlaps an acoustic reflector, such as the air cavity 12, and is between the first electrode 14 and the second electrode 18. The active region can correspond to where voltage is applied on opposing sides of the piezoelectric material layer 16 over the acoustic reflector. The active region can be the acoustically active region of the BAW device 6. The BAW device 6 also includes a recessed frame region with the recessed frame structure 34 in the active region and a raised frame region with the raised frame structure 20 in the active region. The main acoustically active region can provide a main mode of the BAW device 6. The main acoustically active region can be the central part of the active region that is free from frame structures, such as the recessed frame structure 34 and the raised frame structure 20.

While the BAW device 6 includes the recessed frame structure 34 and the raised frame structure 20, other frame structures can alternatively or additionally be implemented. For example, a raised frame structure with multiple layers including a layer between an electrode of a BAW device and the piezoelectric material layer can be implemented. As another example, a floating raised frame structure can be implemented. As one more example, a raised frame structure can be implemented without a recessed frame structure.

One or more conductive layers 17 and 19 can connect an electrode of the BAW device 6 to one or more other BAW devices, one or more integrated passive devices, one or more other circuit elements, one or more signal ports, the like, or any suitable combination thereof. An adhesion layer 15 can be positioned between the conductive layer 17 and an underlying layer to increase adhesion between the layers. The adhesion layer 15 can be a titanium layer, for example.

FIG. 3B is an example plan view of the BAW device 6 of FIG. 3A. The cross-sectional view of FIG. 3A can be along the line from A to A′ in FIG. 3B. In FIG. 3B, the frame region FRAME and the main acoustically active region MAIN are shown. As illustrated, the main acoustically active region MAIN can include the majority of the area of the BAW device 6. The frame region FRAME includes the recessed frame structure 34 and the raised frame structure 20 of the BAW device 6 of FIG. 3A. FIG. 3B illustrates the BAW device 6 with a pentagon shape with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides.

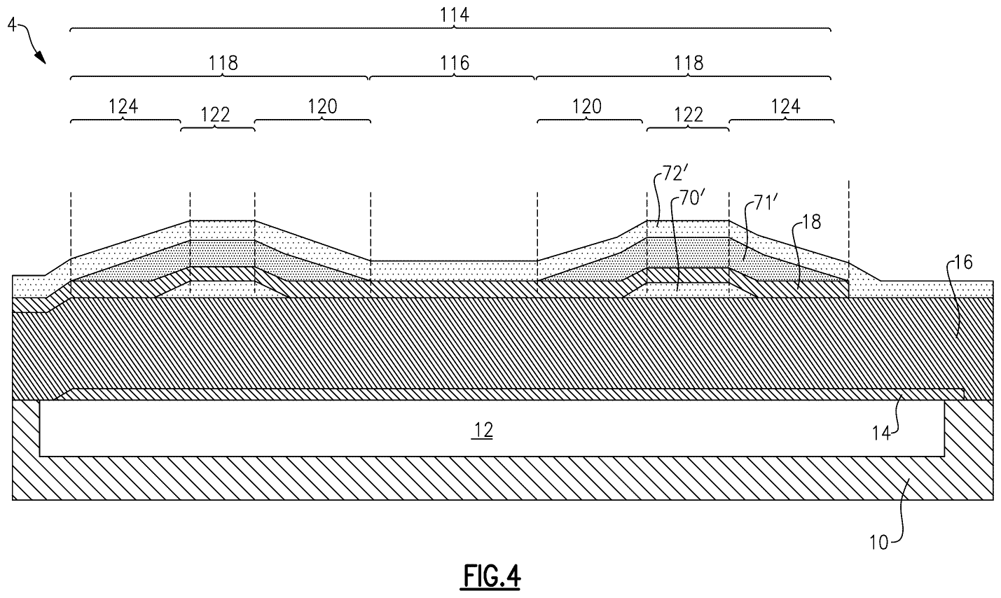

FIGS. 4 and 5 are cross-sectional side views of embodiments of BAW devices 4, 5 with multi-gradient raised frame structures. Any suitable combination of features of these embodiments can be implemented together with each other and/or other embodiments disclosed herein. For example, one or more BAW devices with a multi-gradient raised frame structure can be included in a filter in accordance with any suitable principles and advantages disclosed herein.

FIG. 4 is a schematic cross-sectional side view of a BAW device 4 with a dual gradient raised frame structure according to an embodiment. The device 4 has an active region 114 that includes a main acoustically active region 116 and frame region 118. As illustrated, the frame region 118 is a raised frame region. One or more recessed frame regions can also be included. The frame region 118 can be positioned on opposing sides of the main acoustically active region 116 in the illustrated cross-sectional view. There can be a significant (e.g., exponential) fall off of acoustic energy in the piezoelectric material layer 16 for a main mode in the frame region 118 relative to the main acoustically active region 116. In the frame region 118, there is a first gradient region 120, a non-gradient region 122, and a second gradient region 124. The first raised frame structure 70′ (e.g., an oxide layer) and the second raised frame structure 71′ (e.g., a metal layer) are both substantially parallel to the piezoelectric material layer 16 in the non-gradient region 122. The second raised frame structure 71′ is tapered and extends beyond the first raised frame structure 70′ in the first and second gradient regions 120, 124. The second raised frame structure 71′ has a non-gradient portion in the non-gradient region 122 and gradient portions in the gradient regions 120, 124. A passivation layer 72′ can be positioned over the second raised frame structure 71′.

Although embodiments disclosed herein include dual gradient raised frame structures, any suitable principles and advantages disclosed herein can be implemented in BAW devices with three or more gradient regions. While the frame region 118 of FIG. 4A includes two gradient regions 120, 124 and a non-gradient region 122 between the gradient regions 120, 124, some other multi-gradient raised frame structures (e.g., raised frame structures with relatively narrow width) can include gradient regions without a non-gradient region. Accordingly, a multi-gradient raised frame structure can consist of or consist essentially of gradient regions.

Any suitable principles and advantages disclosed herein can be applied to floating raised frame structures where a raised frame structure is at a floating voltage level. The floating raised frame structure can be electrically isolated from the electrodes of the BAW device (e.g., by a dielectric material).

The BAW devices 1, 2, 3, 4, and 6 of FIGS. 1, 2A, 2B, 3A, 3B, and 4 are examples of film bulk acoustic wave resonators. Any suitable principles and advantages disclosed herein can be applied to other BAW devices. FIG. 5 illustrates a BAW solidly mounted resonator (BAW-SMR) 5 with a dual gradient raised frame structure. The BAW-SMR 5 includes a solid acoustic mirror 132 positioned over a support substrate 130 in place of an air cavity as an acoustic reflector below a lower electrode 14. Any suitable principles and advantages disclosed herein can be applied to SMRs.

BAW devices can include a multi-layer raised frame structure with a plurality of gradients. The multi-layer raised frame structure can include a first raised frame layer positioned between a lower electrode and an upper electrode of a BAW device. The multi-layer raised frame structure can also include a second raised frame layer positioned over the first raised frame layer. The second raised frame layer can extend beyond the first raised frame layer. The second raised frame layer can be tapered on opposing sides where the second raised frame layer extends beyond the first raised frame layer. Tapered portions of the second raised frame layer can have a taper angle that is less than 90 degrees. The multi-layer raised frame structure can have a convex structure relative to a surface of a piezoelectric material layer and/or an electrode layer. The multi-layer raised frame structure can form a dome shaped structure. The multi-layer raised frame structure can surround a main acoustically active region of a BAW acoustic wave device in a plan view.

A gradient portion of a raised frame layer can have a taper angle α with respect to a horizontal direction in the illustrated schematic cross-sectional views. The taper angle α can be with respect to an underlying layer (e.g., a piezoelectric material layer). The taper angle α can be less than 90°. In some embodiments, the taper angle can be less than 40° for a gradient portion of a raised frame layer in a gradient region. In some instances, the taper angle can be in a range from about 10° to 30° for a gradient portion of a raised frame layer in a gradient region.

BAW devices disclosed herein can be implemented in acoustic wave filters. In certain embodiments, the acoustic wave filters can be band pass filters arranged to pass a radio frequency band and attenuate frequencies outside of the radio frequency band. Acoustic wave filters can implement band rejection filters. Two or more acoustic wave filters can be coupled together at a common node and arranged as a multiplexer, such as a duplexer. Example filter topologies include a ladder filter, a lattice filter, a hybrid ladder lattice filter, and the like. An acoustic wave filter can include all BAW devices or one or more BAW devices and one or more other types of acoustic wave resonators such as a SAW resonator. BAW devices disclosed herein can be implemented in a filter that includes at least one BAW device and a non-acoustic inductor-capacitor component.

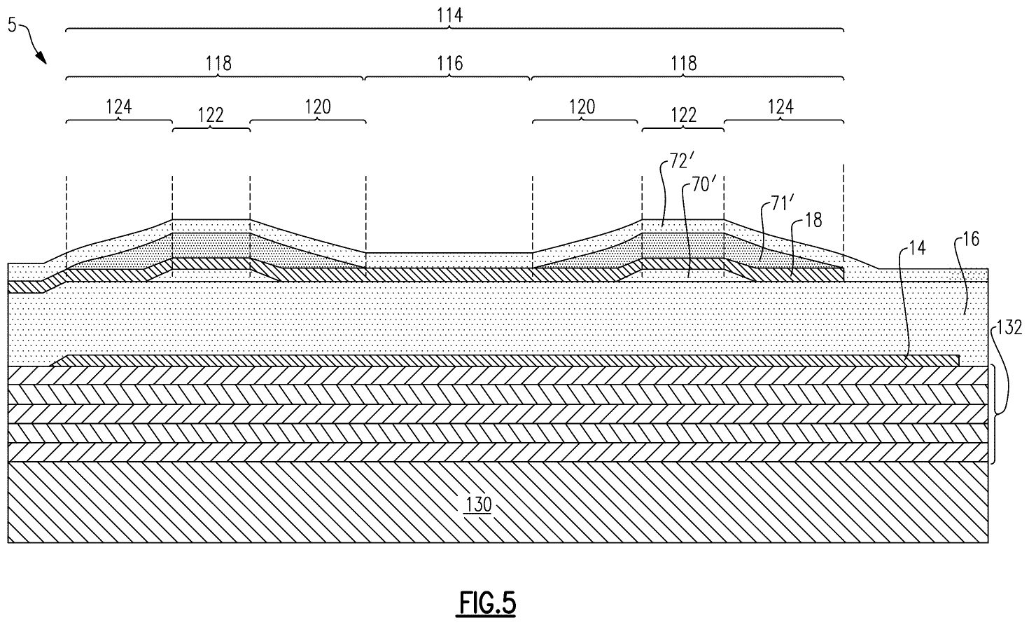

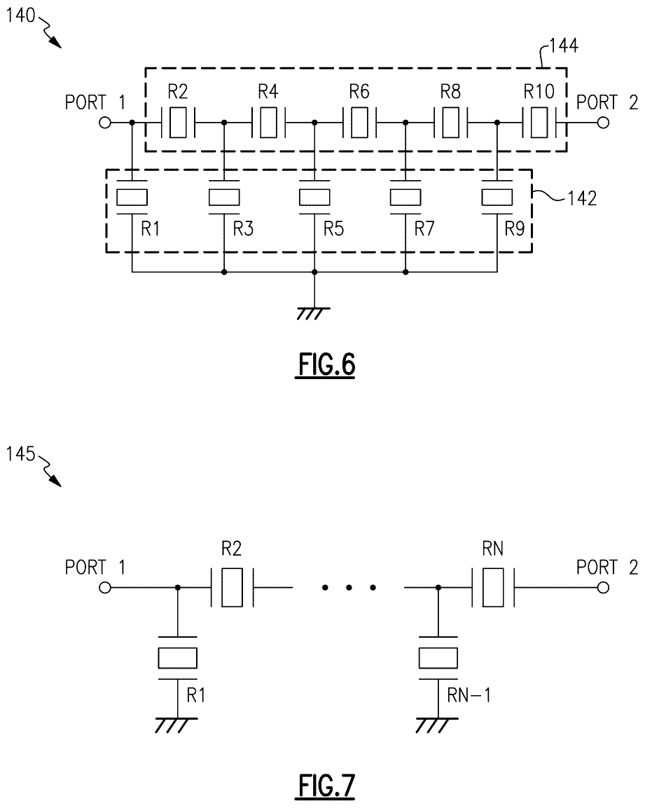

FIG. 6 is a schematic diagram of a ladder filter 140 according to an embodiment. The ladder filter 140 includes shunt BAW resonators 142 and series BAW resonators 144 coupled between RF input/output ports PORT 1 and PORT 2. The ladder filter 140 is an example topology of a band pass filter formed from acoustic resonators. In a band pass filter with a ladder filter topology, the shunt resonators can have lower resonant frequencies than the series resonators. The ladder filter 140 can be arranged to filter an RF signal. As illustrated, the shunt BAW resonators include resonators R1, R3, R5, R7, and R9. The illustrated series BAW resonators 144 include resonators R2, R4, R6, R8, and R10. The first RF input/output port PORT 1 can be a transmit port for a transmit filter or a receive port for a receive filter. The second RF input/output port PORT 2 can be an antenna port. Any suitable number of series acoustic wave resonators can be included in a ladder filter. Any suitable number of shunt acoustic wave resonators can be included in a ladder filter.

In a band rejection filter, the resonators R2, R4, R6, R8, and R10 can include at least one first type of BAW resonator having one or more electrodes manufactured from a first type of material having a low resistivity, a high elastic modulus and a low density as disclosed herein and the resonators R1, R3, R5, R7, and R9 can include at least one second type of BAW resonator having one or more electrodes manufactured from a second type of material, different from the first type of material.

FIG. 7 is a schematic diagram of a ladder filter 145 according to another embodiment. The ladder filter 145 includes a plurality of acoustic resonators R1, R2, . . . , RN−1, and RN arranged between a first input/output port PORT 1 and a second input/output port PORT 2. One of the input/output ports PORT 1 or PORT 2 can be an antenna port. In certain instances, the other of the input/output ports PORT 1 or PORT 2 can be a receive port. In some other instances, the other of the input/output ports PORT 1 or PORT 2 can be a transmit port.

The ladder filter 145 illustrates that any suitable number of ladder stages can be implemented in a ladder filter in accordance with any suitable principles and advantages disclosed herein. Ladder stages can start with a series resonator or a shunt resonator from any input/output port of the ladder filter 145 as suitable. As illustrated, the first ladder stage from the input/output port PORT 1 begins with a shunt resonator R1. As also illustrated, the first ladder stage from the input/output port PORT 2 begins with a series resonator RN.

The ladder filter 145 includes shunt resonators R1 and RN−1 and series resonator R2 and RN. The series resonators of the ladder filter 145 including resonators R2 and RN can be acoustic wave resonators of a first type of BAW resonator. The shunt resonators of the ladder filter 145 including resonators R1 and RN−1 can be acoustic wave resonators of a second type of BAW resonator.

The resonators of the first type can be BAW resonators having one or more electrodes manufactured from a first type of material and the resonators of the second type can be BAW resonators having one or more electrodes manufactured from a second type of material, different from the first type of material. Accordingly, the ladder filter 145 can include series BAW resonators and shunt BAW resonators in certain embodiments. Such BAW resonators can include film bulk acoustic wave resonators and/or solidly mounted resonators (SMRs).

In a band pass filter with a ladder filter topology, such as an acoustic wave filter, the shunt resonators can have lower resonant frequencies than the series resonators. In certain embodiments, the series resonators of the acoustic wave filter 145 are BAW resonators with high acoustic velocity electrodes and the shunt resonators of the acoustic wave filter 145 are BAW resonators with electrodes having a lower acoustic velocity than the electrodes of the series BAW resonators. In such embodiments, the acoustic wave filter 145 can be a band pass filter. Such a band pass filter can achieve low insertion loss at both a lower band edge and an upper band edge of a passband.

In a band stop filter with a ladder filter topology, such as an acoustic wave filter, the shunt resonators can have higher resonant frequencies than the series resonators. In certain embodiments, the acoustic wave filter 145 is a band stop filter, the shunt resonators of the acoustic wave filter 145 are BAW resonators with high acoustic velocity electrodes and the series resonators of the acoustic wave filter 145 are BAW resonators with electrodes having a lower acoustic velocity than the electrodes of the shunt BAW resonators. Such a band stop filter can achieve desirable characteristics in a stop band of the band stop filter.

FIG. 8 is a schematic diagram of a lattice filter 250 that includes one or more BAW resonators according to an embodiment. The lattice filter 250 is an example topology that can form a band pass filter from acoustic wave resonators. The lattice filter 250 can be arranged to filter an RF signal. As illustrated, the lattice filter 250 includes acoustic wave resonators RL1, RL2, RL3, and RL4. The acoustic wave resonators RL1 and RL2 are series resonators. The acoustic wave resonators RL3 and RL4 are shunt resonators. The illustrated lattice filter 250 has a balanced input and a balanced output. One or more of the illustrated acoustic wave resonators RL1 to RL4 can be a BAW resonator in accordance with any suitable principles and advantages disclosed herein.

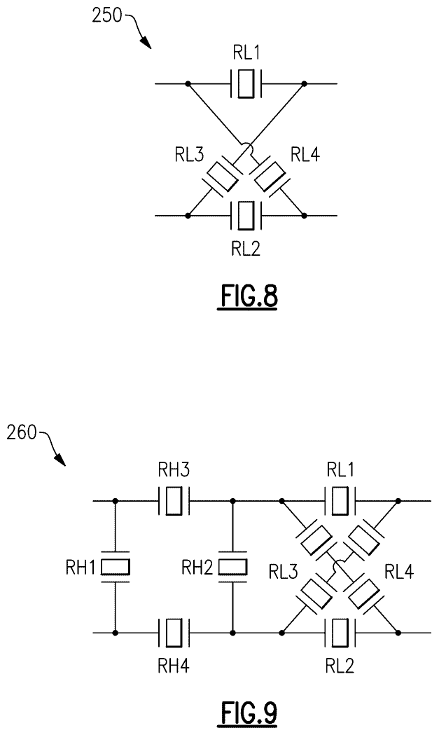

FIG. 9 is a schematic diagram of a hybrid ladder and lattice filter 260 that includes one or more BAW resonators according to an embodiment. The illustrated hybrid ladder and lattice filter 260 includes series acoustic wave resonators RL1, RL2, RH3, and RH4 and shunt acoustic resonators RL3, RL4, RH1, and RH2. The hybrid ladder and lattice filter 260 includes one or more BAW resonators in accordance with any suitable principles and advantages disclosed herein.

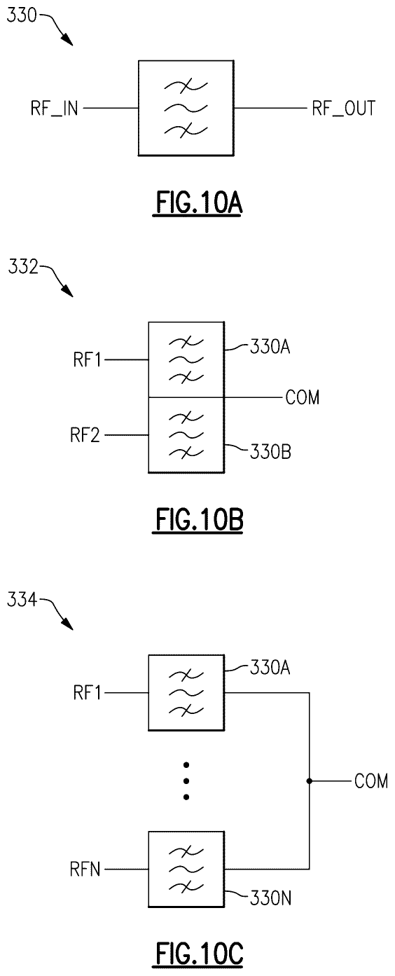

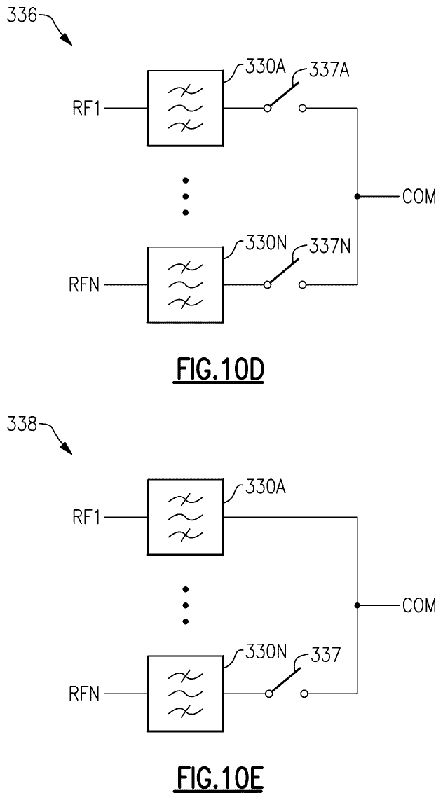

The principles and advantages disclosed herein can be implemented in a standalone filter and/or in one or more filters in any suitable multiplexer. Such filters can be any suitable topology discussed herein, such as any filter topology in accordance with any suitable principles and advantages disclosed with reference to FIGS. 6, 7, 8, and 9. The filter can be a band pass filter arranged to filter a fourth generation (4G) Long Term Evolution (LTE) band and/or a fifth generation (5G) New Radio (NR) band. Examples of a standalone filter and multiplexers will be discussed with reference to FIGS. 10A to 10E. Any suitable principles and advantages of these filters and/or multiplexers can be implemented together with each other. Moreover, the BAW resonators disclosed herein can be included in filters that also include one or more inductors and/or one or more capacitors.

FIG. 10A is a schematic diagram of an acoustic wave filter 330. The acoustic wave filter 330 is a band pass filter. The acoustic wave filter 330 is arranged to filter a radio frequency signal. The acoustic wave filter 330 includes a plurality of acoustic wave resonators coupled between a first input/output port RF_IN and a second input/output port RF_OUT. The acoustic wave filter 330 includes one or more BAW resonators implemented in accordance with any suitable principles and advantages disclosed herein.

FIG. 10B is a schematic diagram of a duplexer 332 that includes an acoustic wave filter according to an embodiment. The duplexer 332 includes a first filter 330A and a second filter 330B coupled together at a common node COM. One of the filters of the duplexer 332 can be a transmit filter and the other of the filters of the duplexer 332 can be a receive filter. In some other instances, such as in a diversity receive application, the duplexer 332 can include two receive filters. Alternatively, the duplexer 332 can include two transmit filters. The common node COM can be an antenna node.

The first filter 330A is an acoustic wave filter arranged to filter a radio frequency signal. The first filter 330A includes acoustic wave resonators coupled between a first radio frequency node RF1 and the common node COM. The first radio frequency node RF1 can be a transmit node or a receive node. The first filter 330A includes one or more BAW resonators implemented in accordance with any suitable principles and advantages disclosed herein.

The second filter 330B can be any suitable filter arranged to filter a second radio frequency signal. The second filter 330B can be, for example, an acoustic wave filter that includes one or more BAW resonators in accordance with any suitable principles and advantages disclosed herein, an LC filter, a hybrid acoustic wave LC filter, or the like. The second filter 330B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implemented in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of BAW resonators in accordance with any suitable principles and advantages disclosed herein.

FIG. 10C is a schematic diagram of a multiplexer 334 that includes an acoustic wave filter according to an embodiment. The multiplexer 334 includes a plurality of filters 330A to 330N coupled together at a common node COM. The plurality of filters can include any suitable number of filters including, for example, 3 filters, 4 filters, 5 filters, 6 filters, 7 filters, 8 filters, or more filters. Some or all of the plurality of filters can be acoustic wave filters. As illustrated, the filters 330A to 330N each have a fixed electrical connection to the common node COM. This can be referred to as hard multiplexing or fixed multiplexing. Filters have fixed electrical connections to the common node in hard multiplexing applications. Each of the filters 330A to 330N has a respective input/output node RF1 to RFN.

The first filter 330A is an acoustic wave filter arranged to filter a radio frequency signal. The first filter 330A can include one or more acoustic wave devices coupled between a first radio frequency node RF1 and the common node COM. The first radio frequency node RF1 can be a transmit node or a receive node. The first filter 330A includes one or more BAW resonators in accordance with any suitable principles and advantages disclosed herein. The other filter(s) of the multiplexer 334 can include one or more acoustic wave filters, one or more acoustic wave filters that include one or more BAW resonators in accordance with any suitable principles and advantages disclosed herein, one or more LC filters, one or more hybrid acoustic wave LC filters, or any suitable combination thereof.

FIG. 10D is a schematic diagram of a multiplexer 336 that includes an acoustic wave filter according to an embodiment. The multiplexer 336 is like the multiplexer 334 of FIG. 10C, except that the multiplexer 336 implements switched multiplexing. In switched multiplexing, a filter is coupled to a common node via a switch. In the multiplexer 336, the switches 337A to 337N can selectively electrically connect respective filters 330A to 330N to the common node COM. For example, the switch 337A can selectively electrically connect the first filter 330A to the common node COM via the switch 337A. Any suitable number of the switches 337A to 337N can electrically connect a respective filters 330A to 330N to the common node COM in a given state. Similarly, any suitable number of the switches 337A to 337N can electrically isolate a respective filter 330A to 330N to the common node COM in a given state. The functionality of the switches 337A to 337N can support various carrier aggregations.

FIG. 10E is a schematic diagram of a multiplexer 338 that includes an acoustic wave filter according to an embodiment. The multiplexer 338 illustrates that a multiplexer can include any suitable combination of hard multiplexed and switched multiplexed filters. One or more BAW resonators in accordance with any suitable principles and advantages disclosed herein can be included in a filter that is hard multiplexed to the common node of a multiplexer. Alternatively or additionally, one or more BAW resonators in accordance with any suitable principles and advantages disclosed herein can be included in a filter that is switch multiplexed to the common node of a multiplexer.

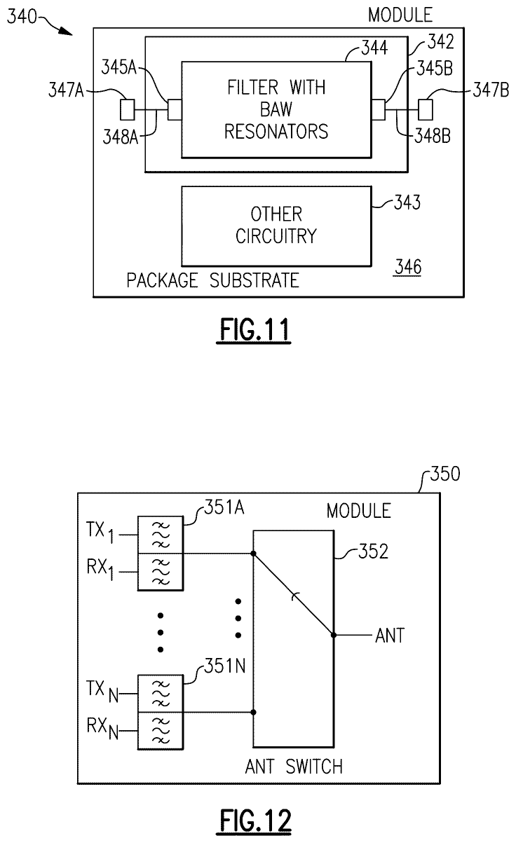

BAW resonators disclosed herein can be implemented in a variety of packaged modules. Some example packaged modules will now be discussed in which any suitable principles and advantages of the BAW devices disclosed herein can be implemented. Example packaged modules include one or more acoustic wave filters and one or more radio frequency amplifiers (e.g., one or more power amplifiers and/or one or more low noise amplifiers) and/or one or more radio frequency switches. The example packaged modules can include a package that encloses the illustrated circuit elements. The illustrated circuit elements can be disposed on a common packaging substrate. The packaging substrate can be a laminate substrate, for example. FIGS. 11 to 15 are schematic block diagrams of illustrative packaged modules according to certain embodiments. Any suitable combination of features of these packaged modules can be implemented with each other. While duplexers are illustrated in the example packaged modules of FIGS. 11 to 15, any other suitable multiplexer that includes a plurality of filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

FIG. 11 is a schematic diagram of a radio frequency module 340 that includes an acoustic wave component 342 according to an embodiment. The illustrated radio frequency module 340 includes the acoustic wave component 342 and other circuitry 343. The acoustic wave component 342 can include one or more BAW resonators in accordance with any suitable combination of features disclosed herein. The acoustic wave component 342 can include a BAW die that includes BAW resonators.

The acoustic wave component 342 shown in FIG. 11 includes a filter 344 and terminals 345A and 345B. The filter 344 includes one or more BAW resonators implemented in accordance with any suitable principles and advantages disclosed herein. The terminals 345A and 345B can serve, for example, as an input contact and an output contact. The acoustic wave component 342 and the other circuitry 343 are on a common packaging substrate 346 in FIG. 11. The packaging substrate 346 can be a laminate substrate. The terminals 345A and 345B can be electrically connected to contacts 347A and 347B, respectively, on the packaging substrate 346 by way of electrical connectors 348A and 348B, respectively. The electrical connectors 348A and 348B can be bumps or wire bonds, for example.

The other circuitry 343 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. The other circuitry 343 can be electrically connected to the filter 344. The radio frequency module 340 can include one or more packaging structures to, for example, provide protection and/or facilitate easier handling of the radio frequency module 340. Such a packaging structure can include an overmold structure formed over the packaging substrate 346. The overmold structure can encapsulate some or all of the components of the radio frequency module 340.

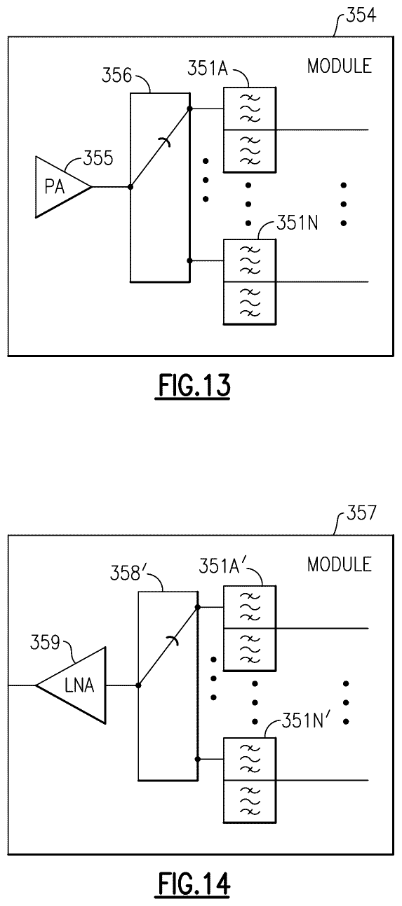

FIG. 12 is a schematic block diagram of a module 350 that includes multiplexers 351A to 351N and an antenna switch 352. One or more filters of the multiplexers 351A to 351N can include one or more BAW resonators in accordance with any suitable principles and advantages discussed herein. Any suitable number of multiplexers 351A to 351N can be implemented. The antenna switch 352 can have a number of throws corresponding to the number of multiplexers 351A to 351N. The antenna switch 352 can include one or more additional throws coupled to one or more filters external to the module 350 and/or coupled to other circuitry. The antenna switch 352 can electrically couple a selected duplexer to an antenna port of the module 350. The multiplexers 351A to 351N can include one or more duplexers.

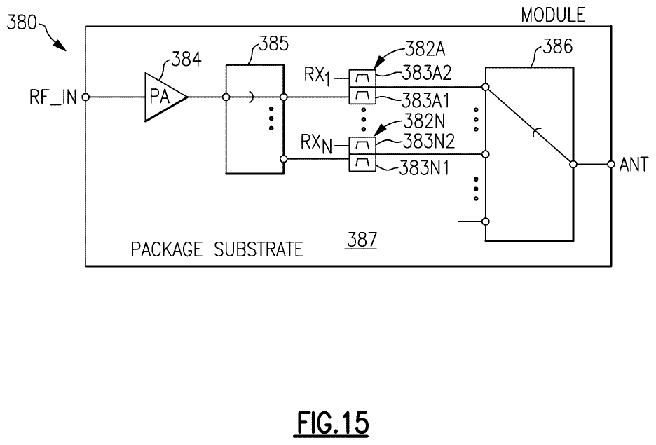

FIG. 13 is a schematic block diagram of a module 354 that includes a power amplifier 355, a radio frequency switch 356, and multiplexers 351A to 351N in accordance with one or more embodiments. The power amplifier 355 can amplify a radio frequency signal. The radio frequency switch 356 can be a multi-throw radio frequency switch. The radio frequency switch 356 can electrically couple an output of the power amplifier 355 to a selected transmit filter of the multiplexers 351A to 351N. One or more filters of the multiplexers 351A to 351N can include any suitable number of BAW resonators in accordance with any suitable principles and advantages discussed herein. Any suitable number of multiplexers 351A to 351N can be implemented.

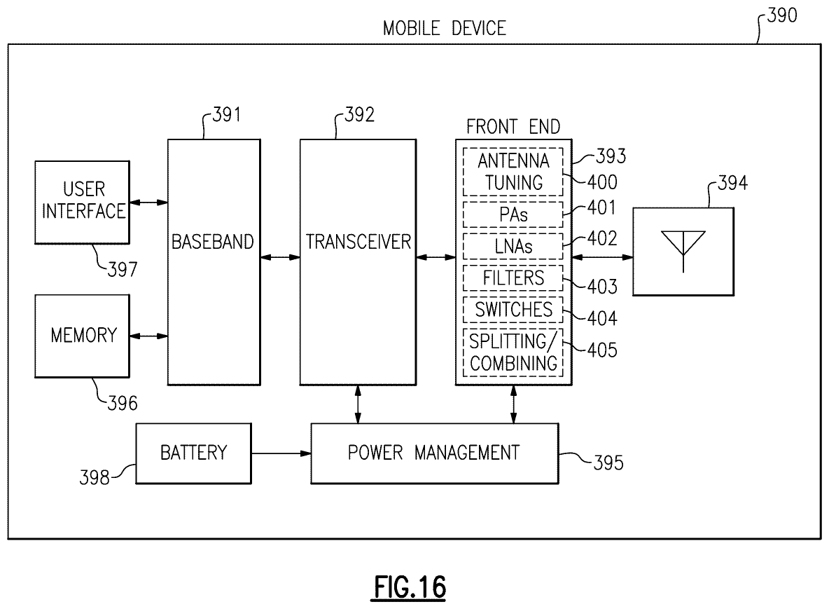

FIG. 14 is a schematic block diagram of a module 357 that includes multiplexers 351A′ to 351N′, a radio frequency switch 358′, and a low noise amplifier 359 according to an embodiment. One or more filters of the multiplexers 351A′ to 351N′ can include any suitable number BAW resonators in accordance with any suitable principles and advantages disclosed herein. Any suitable number of multiplexers 351A′ to 351N′ can be implemented. The radio frequency switch 358′ can be a multi-throw radio frequency switch. The radio frequency switch 358′ can electrically couple an output of a selected filter of multiplexers 351A′ to 351N′ to the low noise amplifier 359. In some embodiments (not illustrated), a plurality of low noise amplifiers can be implemented. The module 357 can include diversity receive features in certain applications.

FIG. 15 is a schematic diagram of a radio frequency module 380 that includes an acoustic wave filter according to an embodiment. As illustrated, the radio frequency module 380 includes duplexers 382A to 382N that include respective transmit filters 383A1 to 383N1 and respective receive filters 383A2 to 383N2, a power amplifier 384, a select switch 385, and an antenna switch 386. The radio frequency module 380 can include a package that encloses the illustrated elements. The illustrated elements can be disposed on a common packaging substrate 387. The packaging substrate 387 can be a laminate substrate, for example. A radio frequency module that includes a power amplifier can be referred to as a power amplifier module. A radio frequency module can include a subset of the elements illustrated in FIG. 15 and/or additional elements. The radio frequency module 380 may include one or more BAW resonators in accordance with any suitable principles and advantages disclosed herein.

The duplexers 382A to 382N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters 383A1 to 383N1 can include one or more BAW resonators in accordance with any suitable principles and advantages disclosed herein. Similarly, one or more of the receive filters 383A2 to 383N2 can include one or more BAW resonators in accordance with any suitable principles and advantages disclosed herein. Although FIG. 15 illustrates duplexers, any suitable principles and advantages disclosed herein can be implemented in other multiplexers (e.g., quadplexers, hexaplexers, octoplexers, etc.) and/or in switched multiplexers.

The power amplifier 384 can amplify a radio frequency signal. The illustrated switch 385 is a multi-throw radio frequency switch. The switch 385 can electrically couple an output of the power amplifier 384 to a selected transmit filter of the transmit filters 383A1 to 383N1. In some instances, the switch 385 can electrically connect the output of the power amplifier 384 to more than one of the transmit filters 383A1 to 383N1. The antenna switch 386 can selectively couple a signal from one or more of the duplexers 382A to 382N to an antenna port ANT. The duplexers 382A to 382N can be associated with different frequency bands and/or different modes of operation (e.g., different power modes, different signaling modes, etc.).

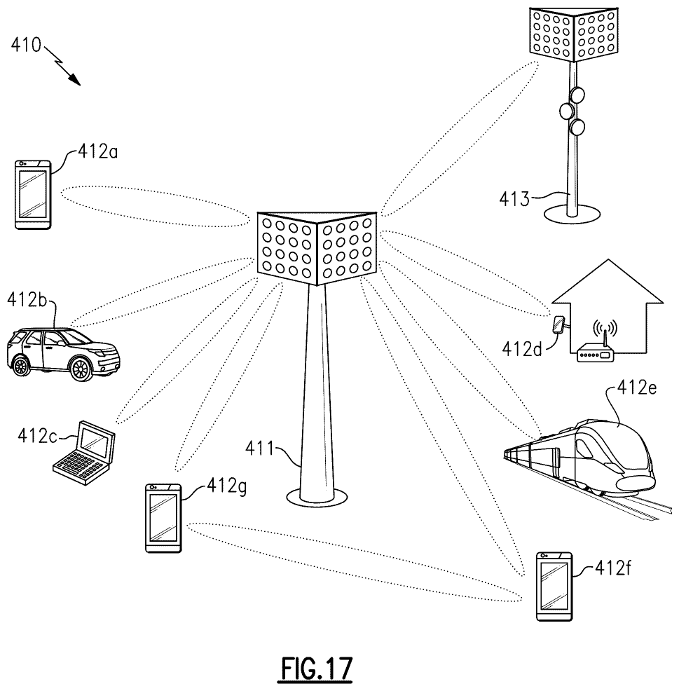

BAW devices with high acoustic velocity electrodes as disclosed herein can be implemented in a variety of wireless communication devices, such as mobile devices. One or more filters with any suitable number of BAW devices implemented with any suitable principles and advantages disclosed herein can be included in a variety of wireless communication devices, such as mobile phones. The BAW devices can be included in a filter of a radio frequency front end (RFFE). FIG. 16 is a schematic diagram of one embodiment of a mobile device 390. The mobile device 390 includes a baseband system 391, a transceiver 392, a front end system 393, antennas 394, a power management system 395, a memory 396, a user interface 397, and a battery 398.

The mobile device 390 can be used communicate using a wide variety of communications technologies, including, but not limited to, second generation (2G), third generation (3G), fourth generation (4G) (including LTE, LTE-Advanced, and LTE-Advanced Pro), fifth generation (5G) New Radio (NR), wireless local area network (WLAN) (for instance, WiFi), wireless personal area network (WPAN) (for instance, Bluetooth and ZigBee), WMAN (wireless metropolitan area network) (for instance, WiMax), Global Positioning System (GPS) technologies, or any suitable combination thereof. The transceiver 392 generates RF signals for transmission and processes incoming RF signals received from the antennas 394. It will be understood that various functionalities associated with the transmission and receiving of RF signals can be achieved by one or more components that are collectively represented in FIG. 16 as the transceiver 392. In one example, separate components (for instance, separate circuits or dies) can be provided for handling certain types of RF signals.

The front end system 393 aids in conditioning signals transmitted to and/or received from the antennas 394. In the illustrated embodiment, the front end system 393 includes antenna tuning circuitry 400, power amplifiers (PAs) 401, low noise amplifiers (LNAs) 402, filters 403, switches 404, and signal splitting/combining circuitry 405. However, other implementations are possible. One or more of the filters 403 can be implemented in accordance with any suitable principles and advantages disclosed herein. For example, one or more of the filters 403 can include at least one BAW resonator with high acoustic velocity electrodes in accordance with any suitable principles and advantages disclosed herein.

For example, the front end system 393 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, duplexing or triplexing), or any suitable combination thereof.

In certain implementations, the mobile device 390 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 394 can include antennas used for a wide variety of types of communications. For example, the antennas 394 can include antennas for transmitting and/or receiving signals associated with a wide variety of frequencies and communications standards. In certain implementations, the antennas 394 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 390 can operate with beamforming in certain implementations. For example, the front end system 393 can include amplifiers having controllable gain and phase shifters having controllable phase to provide beam formation and directivity for transmission and/or reception of signals using the antennas 394. For example, in the context of signal transmission, the amplitude and phases of the transmit signals provided to the antennas 394 are controlled such that radiated signals from the antennas 394 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 394 from a particular direction. In certain implementations, the antennas 394 include one or more arrays of antenna elements to enhance beamforming.

The baseband system 391 is coupled to the user interface 397 to facilitate processing of various user input and output (I/O), such as voice and data. The baseband system 391 provides the transceiver 392 with digital representations of transmit signals, which the transceiver 392 processes to generate RF signals for transmission. The baseband system 391 also processes digital representations of received signals provided by the transceiver 392. As shown in FIG. 16, the baseband system 391 is coupled to the memory 396 to facilitate operation of the mobile device 390. The memory 396 can be used for a wide variety of purposes, such as storing data and/or instructions to facilitate the operation of the mobile device 390 and/or to provide storage of user information.

The power management system 395 provides a number of power management functions of the mobile device 390. In certain implementations, the power management system 395 includes a PA supply control circuit that controls the supply voltages of the power amplifiers 401. For example, the power management system 395 can be configured to change the supply voltage(s) provided to one or more of the power amplifiers 401 to improve efficiency, such as power added efficiency (PAE). As shown in FIG. 16, the power management system 395 receives a battery voltage from the battery 398. The battery 398 can be any suitable battery for use in the mobile device 390, including, for example, a lithium-ion battery.

The teachings herein are applicable to a wide variety of communication systems, including, but not limited to, communication systems using advanced cellular technologies, such as LTE-Advanced, LTE-Advanced Pro, and/or 5G NR. An acoustic wave device including any suitable combination of features disclosed herein can be included in a filter arranged to filter a radio frequency signal in a 5G NR operating band within Frequency Range 1 (FR1). A filter arranged to filter a radio frequency signal in a 5G NR operating band can include one or more BAW devices disclosed herein. FR1 can be from 410 MHz to 7.125 GHz, for example, as specified in a current 5G NR specification. One or more BAW devices in accordance with any suitable principles and advantages disclosed herein can be included in a filter arranged to filter a radio frequency signal in fourth generation (4G) Long Term Evolution (LTE). One or more BAW devices in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio Dual Connectivity (ENDC) application.

BAW devices disclosed herein can provide high resonant frequencies and/or desirable power ruggedness. Such features can be advantageous in 5G NR applications. For example, such filters can filter RF signals within high frequency bands. At the same time, the filters can have desirable power ruggedness for meeting 5G performance specifications at the filter level and/or at the system level.

FIG. 17 is a schematic diagram of one example of a communication network 410. The communication network 410 includes a macro cell base station 411, a small cell base station 413, and various examples of user equipment (UE), including a first mobile device 412a, a wireless-connected car 412b, a laptop 412c, a stationary wireless device 412d, a wireless-connected train 412e, a second mobile device 412f, and a third mobile device 412g. UEs are wireless communication devices. One or more of the macro cell base station 411, the small cell base station 413, or UEs illustrated in FIG. 17 can implement one or more of the acoustic wave filters in accordance with any suitable principles and advantages disclosed herein. For example, one or more of the UEs shown in FIG. 17 can include one or more acoustic wave filters that include any suitable number of BAW resonators in accordance with any suitable principles and advantages disclosed herein.

Although specific examples of base stations and user equipment are illustrated in FIG. 17, a communication network can include base stations and user equipment of a wide variety of types and/or numbers. For instance, in the example shown, the communication network 410 includes the macro cell base station 411 and the small cell base station 413. The small cell base station 413 can operate with relatively lower power, shorter range, and/or with fewer concurrent users relative to the macro cell base station 411. The small cell base station 413 can also be referred to as a femtocell, a picocell, or a microcell. Although the communication network 410 is illustrated as including two base stations, the communication network 410 can be implemented to include more or fewer base stations and/or base stations of other types.

Although various examples of user equipment are shown, the teachings herein are applicable to a wide variety of user equipment, including, but not limited to, mobile phones, tablets, laptops, Internet of Things (IoT) devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 410 of FIG. 17 supports communications using a variety of cellular technologies, including, for example, 4G LTE and 5G NR. In certain implementations, the communication network 410 is further adapted to provide a wireless local area network (WLAN), such as WiFi. Although various examples of communication technologies have been provided, the communication network 410 can be adapted to support a wide variety of communication technologies.

Various communication links of the communication network 410 have been depicted in FIG. 17. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 17, the communication links include not only communication links between UE and base stations, but also UE to UE communications and base station to base station communications. For example, the communication network 410 can be implemented to support self-fronthaul and/or self-backhaul (for instance, as between mobile device 412g and mobile device 412f).

The communication links can operate over a wide variety of frequencies. In certain implementations, communications are supported using 5G NR technology over one or more frequency bands that are less than 6 GHz and/or over one or more frequency bands that are greater than 6 GHz. According to certain implementations, the communication links can serve Frequency Range 1 (FR1), Frequency Range 2 (FR2), or a combination thereof. An acoustic wave filter in accordance with any suitable principles and advantages disclosed herein can filter a radio frequency signal within FR1. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 410 can share available network resources, such as available frequency spectrum, in a wide variety of ways. In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 3 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 410 of FIG. 17 can be used to support a wide variety of advanced communication features, including, but not limited to, eMBB, uRLLC, and/or mMTC.

Bulk acoustic wave devices disclosed herein can be included in a filter and/or a multiplexer arranged to filter a radio frequency signal in a fifth generation (5G) New Radio (NR) operating band within Frequency Range 1 (FR1). FR1 can range from 410 megahertz (MHz) to 7.125 gigahertz (GHz), for example, as specified in a current 5G NR specification. A filter arranged to filter a radio frequency signal in a 5G NR FR1 operating band can include one or more bulk acoustic wave resonators be implemented in accordance with any suitable principles and advantages disclosed herein.

5G NR carrier aggregation specifications can present technical challenges. For example, 5G carrier aggregations can have wider bandwidth and/or channel spacing than fourth generation (4G) Long Term Evolution (LTE) carrier aggregations. Carrier aggregation bandwidth in certain 5G FR1 applications can be in a range from 120 MHz to 400 MHz, such as in a range from 120 MHz to 200 MHz. Carrier spacing in certain 5G FR1 applications can be up to 100 MHz. Bulk acoustic wave resonators with high acoustic velocity electrodes as disclosed herein can achieve low insertion loss and low Gamma loss while providing for flexibility in the operating frequencies. Accordingly, the operating frequencies of such BAW resonators can be placed outside of a carrier aggregation band even with the wider carrier aggregation bandwidth and/or channel spacing within FR1 in 5G specifications. This can reduce and/or eliminate Gamma degradation in an operating band of another carrier of a carrier aggregation. In some instances, Gamma can be increased in the operating band of the other carrier of the carrier aggregation.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smartphone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled,” as generally used herein, refers to two or more elements that may be either directly coupled, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

1. A bulk acoustic wave (BAW) device comprising:
a first electrode and a second electrode, at least one of the first electrode and the second electrode including at least one of a binary intermetallic compound, a metal nitride, a metal carbide, a metal carbonitride, a metal boride, a MXene, a MAX phase, or a MAB phase; and
a piezoelectric material layer positioned between the first electrode and the second electrode.

2. The BAW device of claim 1 further comprising a raised frame structure outside of a middle area of an active region of the BAW device, the raised frame structure including a raised frame layer positioned between one of the first and second electrodes and the piezoelectric material layer, the raised frame layer having a lower acoustic impedance than the first or second electrode, at least a part of the raised frame structure including at least one of a binary intermetallic compound, a metal nitride, a metal carbide, a metal carbonitride, a metal boride, a MXene, a MAX phase, or a MAB phase.

3. The BAW device of claim 1 wherein both the first electrode and the second electrode are formed of at least one of a binary intermetallic compound, a metal nitride, a metal carbide, a metal carbonitride, a metal boride, a MXene, a MAX phase, or a MAB phase.

4. The BAW device of claim 3 wherein the first electrode and the second electrode are formed of a same material.

5. The BAW device of claim 3 wherein the first electrode and the second electrode are formed of different materials.

6. The BAW device of claim 1 wherein at least one of the first electrode and the second electrode is formed of one of Al₃Ti, AlTi, AlTi₃, Al₃Sc, NiAl, Ni₃Al, CoAl, CoPt, AlCu, Al₂Cu, Cu₂Mg, or Cu_{0.019}Be.

7. The BAW device of claim 1 wherein at least one of the first electrode and the second electrode is formed of one of TiN, ZrN, HfN, VN, NbN, CrN, or MoN_{0.6}.

8. The BAW device of claim 1 wherein at least one of the first electrode and the second electrode is formed of one of TiC, ZrC, HfC, VC_{0.88}, NbC, TaC, Cr₃C₂, Mo₂C, or WC.

9. The BAW device of claim 1 wherein at least one of the first electrode and the second electrode is formed of one of a-AlB₂, a-TiB₂, a-VB₂, a-WB₂, ZrB₂, HfB₂, NbB₂, TaB₂, CrB₂₋ₓ, or Mo₂B₅₋ₓ.

10. The BAW device of claim 1 wherein at least one of the first electrode and the second electrode is formed of one of Ti₂AlN, Ti₂AlC, Ti₂SiC, Ti₂GeC, Ti₂SnC, Ti₃AlC₂, Ti₃GeC₂, Ti₃SiC₂, Mn₂AlB₂, Fe₂AlB₂, MoAlB, or WAlB.

11. A film bulk acoustic wave resonator device comprising:
a substrate;
first and second conductive layers implemented over the substrate, at least one of the first and second conductive layers including at least one of a binary intermetallic compound, a metal nitride, a metal carbide, a metal carbonitride, a metal boride, a MXene, a MAX phase, or a MAB phase; and
a piezoelectric material layer between the first and second conductive layers.

12. The film bulk acoustic wave resonator device of claim 11 further comprising a raised frame structure outside of a middle area of an active region of the film bulk acoustic wave resonator device, the raised frame structure including a raised frame layer positioned between one of the first and second conductive layers and the piezoelectric material layer, the raised frame layer having a lower acoustic impedance than at least one of the first conductive layer, the second conductive layer, or the piezoelectric material layer.

13. The film bulk acoustic wave resonator device of claim 12 wherein at least a part of the raised frame structure includes at least one of a binary intermetallic compound, a metal nitride, a metal carbide, a metal carbonitride, a metal boride, a MXene, a MAX phase, or a MAB phase.

14. The film bulk acoustic wave resonator device of claim 11 wherein both the first conductive layer and the second conductive layer are formed of at least one of a binary intermetallic compound, a metal nitride, a metal carbide, a metal carbonitride, a metal boride, a MXene, a MAX phase, or a MAB phase.

15. The film bulk acoustic wave resonator device of claim 11 wherein at least one of the first conductive layer and the second conductive layer is formed of one of Al₃Ti, AlTi, AlTi₃, Al₃Sc, NiAl, Ni₃Al, CoAl, CoPt, AlCu, Al₂Cu, Cu₂Mg, or Cu_{0.019}Be.

16. The film bulk acoustic wave resonator device of claim 11 wherein at least one of the first conductive layer and the second conductive layer is formed of one of TiN, ZrN, HfN, VN, NbN, CrN, or MoN_{0.6}.

17. The film bulk acoustic wave resonator device of claim 11 wherein at least one of the first conductive layer and the second conductive layer is formed of one of TiC, ZrC, HfC, VC_{0.88}, NbC, TaC, Cr₃C₂, Mo₂C, or WC.

18. The film bulk acoustic wave resonator device of claim 11 wherein at least one of the first conductive layer and the second conductive layer is formed of one of a-AlB₂, a-TiB₂, a-VB₂, a-WB₂, ZrB₂, HfB₂, NbB₂, TaB₂, CrB₂₋ₓ, or Mo₂B₅₋ₓ.

19. The film bulk acoustic wave resonator device of claim 11 wherein at least one of the first conductive layer and the second conductive layer is formed of one of Ti₂AlN, Ti₂AlC, Ti₂SiC, Ti₂GeC, Ti₂SnC, Ti₃AlC₂, Ti₃GeC₂, Ti₃SiC₂, Mn₂AlB₂, Fe₂AlB₂, MoAlB, or WAlB.

20. A packaged module comprising:
a packaging substrate;
an acoustic wave filter on the packaging substrate configured to filter a radio frequency signal, the acoustic wave filter including a bulk acoustic wave (BAW) device, the BAW device including a first electrode and a second electrode, at least one of the first electrode and the second electrode including at least one of a binary intermetallic compound, a metal nitride, a metal carbide, a metal carbonitride, a metal boride, a MXene, a MAX phase, or a MAB phase, and a piezoelectric material layer positioned between the first electrode and the second electrode; and
a radio frequency component electrically coupled to the acoustic wave filter and positioned on the packaging substrate, the acoustic wave filter and the radio frequency component being enclosed within a common package.
